(19) United States
(12) Patent Application Publication
(10) Pub. No.: US 2026/0150513 A1
(43) Pub. Date: May 28, 2026

(54) DISPLAY PANEL, ELECTRONIC DEVICE, AND METHOD OF MANUFACTURING THE DISPLAY PANEL

(71) Applicant: Samsung Display Co., Ltd., Yongin-si (KR)

(72) Inventors: Changsuk Lee, Yongin-si (KR); Changho Yi, Yongin-si (KR); Daewon Choi, Yongin-si (KR)

(21) Appl. No.: 19/348,625

(22) Filed: Oct. 2, 2025

(30) Foreign Application Priority Data
Nov. 22, 2024 (KR) 10-2024-0168913

(51) Int. Cl. H10K 59/122; H10K 59/12; H10K 59/80

(52) U.S. Cl. CPC H10K 59/122; H10K 59/1201; H10K 59/873

(57) ABSTRACT

A display panel includes: a substrate; a bank layer on the substrate; a light-emitting diode including a sub-pixel electrode, an intermediate layer, and an opposite electrode sequentially on the bank layer; a first encapsulation layer on the opposite electrode, and having a first connecting opening overlapping with the opposite electrode; and an upper electrode on the first encapsulation layer, and connected to the opposite electrode through the first connecting opening in the first encapsulation layer.

### CROSS-REFERENCE TO RELATED APPLICATION

The present application claims priority to and the benefit of Korean Patent Application No. 10-2024-0168913, filed on November 22, 2024, in the Korean Intellectual Property Office, the entire disclosure of which is incorporated by reference herein.

### BACKGROUND

### 1. Field

Aspects of one or more embodiments of the present disclosure relate to a display panel, an electronic device including the display panel, and a method of manufacturing the display panel.

### 2. Description of the Related Art

Display panels visually display data. A display panel may include a substrate including a display area and a peripheral area. A plurality of pixels may be arranged in the display area. A single pixel may include a plurality of sub-pixels. Thin-film transistors respectively corresponding to the sub-pixels, and light-emitting diodes electrically connected to the thin-film transistors, may be located in the display area. A light-emitting diode may include a sub-pixel electrode, an opposite electrode, and an emission layer between the sub-pixel electrode and the opposite electrode. Different voltages may be applied to the sub-pixel electrode and the opposite electrode of the light-emitting diode, and a potential difference may be generated between the sub-pixel electrode and the opposite electrode. A current may flow through the emission layer due to the potential difference, and accordingly, the emission layer may emit light in a desired wavelength band or color (e.g., a specific or predetermined wavelength band or color).

The above information disclosed in this Background section is for enhancement of understanding of the background of the present disclosure, and therefore, it may contain information that does not constitute prior art.

### SUMMARY

When light-emitting diodes are formed, a sub-pixel electrode, an emission layer, and an opposite electrode may be sequentially arranged on a bank layer including a conductive material (e.g., a metal). An insulating layer may be arranged between the sub-pixel electrode and the bank layer, and the opposite electrode may extend downwards while surrounding (e.g., around a periphery of) side surfaces of the emission layer and the sub-pixel electrode, and thus, may contact the side surfaces of the bank layer. The opposite electrode may receive a voltage through the bank layer.

When the structure of the light-emitting diode is formed, there may be a difficulty in implementing a contact between the opposite electrode and the bank layer.

Embodiments of the present disclosure may be directed to a display panel that may stably apply a voltage to the opposite electrode, while maintaining a structure of the light-emitting diodes arranged on and above a bank layer, an electronic device including the display panel, and a method of manufacturing the display panel.

However, the aspects and features of the present disclosure are not limited thereto, and additional aspects and features may be apparent from the following description.

According to one or more embodiments of the present disclosure, a display panel includes: a substrate; a bank layer on the substrate; a light-emitting diode including a sub-pixel electrode, an intermediate layer, and an opposite electrode sequentially on the bank layer; a first encapsulation layer on the opposite electrode, and having a first connecting opening overlapping with the opposite electrode; and an upper electrode on the first encapsulation layer, and connected to the opposite electrode through the first connecting opening in the first encapsulation layer.

In an embodiment, the bank layer may include a first bank layer, and a second bank layer on the first bank layer, and the second bank layer may include a tip extending beyond an edge of the first bank layer.

In an embodiment, the first encapsulation layer may entirely cover the light-emitting diode, and may partially cover the bank layer.

In an embodiment, the display panel may further include a thin-film transistor under the bank layer, and the sub-pixel electrode may be electrically connected to the thin-film transistor through the bank layer.

In an embodiment, the display panel may further include a second encapsulation layer between the first encapsulation layer and the upper electrode and having a second connecting opening overlapping with the first connecting opening in the first encapsulation layer. The upper electrode may be connected to the opposite electrode through the first connecting opening in the first encapsulation layer and the second connecting opening in the second encapsulation layer.

In an embodiment, the display panel may further include a third encapsulation layer covering the upper electrode.

In an embodiment, the display panel may further include a protective layer on the bank layer, and covering an edge region of the sub-pixel electrode.

In an embodiment, a portion of the intermediate layer and a portion of the opposite electrode may be on the protective layer.

In an embodiment, in a plan view, the upper electrode may surround around at least a portion of the light-emitting diode, and may overlap with the light-emitting diode in an area corresponding to the first connecting opening.

According to one or more embodiments of the present disclosure, an electronic device includes: a display panel; and a housing accommodating the display panel. The display panel includes: a substrate; a bank layer on the substrate; a light-emitting diode including a sub-pixel electrode, an intermediate layer, and an opposite electrode sequentially on the bank layer; a first encapsulation layer on the opposite electrode, and having a first connecting opening overlapping with the opposite electrode; and an upper electrode on the first encapsulation layer, and connected to the opposite electrode through the first connecting opening in the first encapsulation layer.

According to one or more embodiments of the present disclosure, a method of manufacturing a display panel, includes: arranging a bank layer on a substrate; arranging, on the bank layer, a light-emitting diode including a sub-pixel electrode, an intermediate layer, and an opposite electrode; arranging a first encapsulation layer on the light-emitting diode; forming a first connecting opening in the first encapsulation layer; and arranging an upper electrode on the first encapsulation layer to be connected to the opposite electrode of the light-emitting diode through the first connecting opening.

In an embodiment, the arranging of the bank layer may include: sequentially arranging a first material layer and a second material layer on the substrate; and forming a first bank layer and a second bank layer by etching each of the first material layer and the second material layer. The second bank layer includes a tip extending beyond an edge of the first bank layer.

In an embodiment, the arranging of the first encapsulation layer may include: arranging a preliminary layer to entirely cover both the light-emitting diode and the bank layer; and forming the first encapsulation layer by etching the preliminary layer. The first encapsulation layer entirely covers the light-emitting diode, and partially covers the bank layer.

In an embodiment, the method may further include: arranging a second encapsulation layer between the upper electrode and the first encapsulation layer; and forming a second connecting opening in the second encapsulation layer, the second connecting opening overlapping with the first connecting opening in the first encapsulation layer.

In an embodiment, the upper electrode is connected to the opposite electrode through the first connecting opening in the first encapsulation layer and the second connecting opening in the second encapsulation layer.

In an embodiment, the method may further include arranging a third encapsulation layer to cover the upper electrode.

In an embodiment, the method may further include arranging a protective layer on the bank layer to cover an edge region of the sub-pixel electrode.

In an embodiment, a portion of the intermediate layer and a portion of the opposite electrode may be arranged on the protective layer.

In an embodiment, the light-emitting diode may entirely overlap with the upper electrode in a plan view in the arranging of the upper electrode.

In an embodiment, in a plan view, the upper electrode may be patterned to partially surround around the light-emitting diode, and may overlap with the light-emitting diode in an area corresponding to the first connecting opening.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a schematic plan view of an electronic device according to an embodiment;

FIG. 2 is a plan view of a portion of a display panel according to an embodiment;

FIG. 3 is a schematic circuit diagram illustrating a light-emitting diode and a sub-pixel circuit of a sub-pixel according to an embodiment;

FIG. 4 is a cross-sectional view of a display panel according to an embodiment;

FIG. 5 is a cross-sectional view of a display panel according to an embodiment;

FIG. 6 is a cross-sectional view of a display panel according to an embodiment;

FIG. 7 is a cross-sectional view of a display panel according to an embodiment;

FIG. 8 is a plan view of a portion of a display panel according to an embodiment;

FIG. 9 is a plan view of a portion of a display panel according to an embodiment;

FIG. 10 is a plan view of a portion of a display panel according to an embodiment; and

FIGS. 11-28 are cross-sectional views illustrating some operations of a method of manufacturing a display panel according to some embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being "electrically connected" to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” "includes," "including," "has," "have," and "having," when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression "A and/or B" denotes A, B, or A and B. Expressions such as “at least one of,” when preceding a list of elements, modify the entire list of elements and do not modify the individual elements of the list. For example, the expression "at least one of a, b, or c," “at least one of a, b, and c,” and “at least one selected from the group consisting of a, b, and c” indicates only a, only b, only c, both a and b, both a and c, both b and c, all of a, b, and c, or variations thereof.

As used herein, the term "substantially," "about," and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms "use," "using," and "used" may be considered synonymous with the terms "utilize," "utilizing," and "utilized," respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

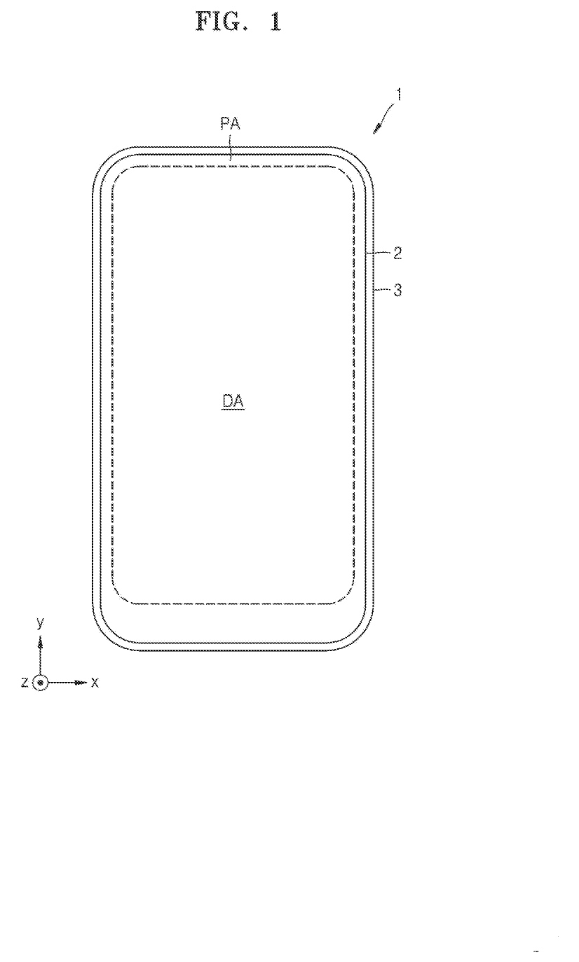

FIG. 1 is a schematic plan view of an electronic device 1 according to an embodiment.

The electronic device 1 may include a display panel 2 and a housing 3. In an embodiment, the display panel 2 may be accommodated in the housing 3.

The electronic device 1 may be used as or implemented as, for example, a portable electric device, such as a mobile phone, a smartphone, a tablet Personal Computer (PC), a mobile communication terminal, a personal digital assistant, an e-book terminal, a Portable Multimedia Player (PMP), a navigation device, an Ultra-Mobile PC (UMPC), and the like, or other suitable electronic device, such as a television (TV), a laptop, a monitor, a billboard, an Internet of Things (IoT) device, and the like. In an embodiment, the electronic device 1 may be used as or implemented as a wearable device, such as a smartwatch, a watch phone, an eyewear display, or a head-mounted display (HMD). In an embodiment, the electronic device 1 may be used as or implemented as a display in an instrument cluster of a vehicle, a Center Information Display (CID) mounted on a center fascia or a dashboard of a vehicle, a mirror display replacing side-view mirrors of a vehicle, or a car headrest monitor for a rear-seat entertainment. In various embodiments, the display panel 2 may be included in the electronic device 1, as described above, as a component for displaying moving images or still images. FIG. 1 illustrates that the electronic device 1 is a smartphone, but the present disclosure is not limited thereto.

The display panel 2 may include a display area DA, and a peripheral area PA on the outer side (e.g., the periphery) of the display area DA.

The display area DA is an area where images are displayed, and a plurality of pixels PX may be arranged in the display area DA. The display area DA may have one of various suitable shapes, for example, such as a circle, an oval, a polygon, or other specific shapes. FIG. 1 illustrates that the display area DA has a rectangular or substantially rectangular shape with rounded edges.

The peripheral area PA may be arranged on the outer side of the display area DA. The peripheral area PA may be located to surround (e.g., around a periphery of) at least a portion of the display area DA.

Hereinafter, an organic light-emitting display panel is described in more detail as an example of the display panel 2 according to an embodiment, but the display panel 2 is not limited thereto. In another embodiment, the display panel 2 may be, for example, an inorganic light-emitting display device or a quantum dot light-emitting display device. For example, an emission layer of a display element included in the display panel 2 may include an organic material, an inorganic material, quantum dots, both an organic material and quantum dots, or both an inorganic material and quantum dots.

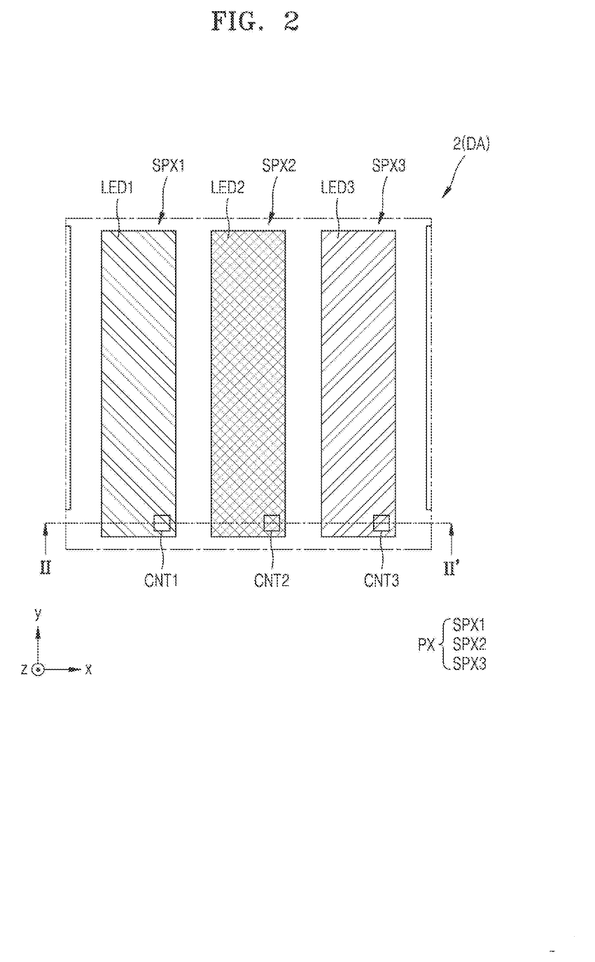

FIG. 2 is a plan view of a portion of the display panel 2 according to an embodiment.

Referring to FIG. 2, the display panel 2 may include pixels PX arranged in the display area DA. In an embodiment, a single pixel PX may include a plurality of sub-pixels. For example, the pixel PX may include a first sub-pixel SPX1, a second sub-pixel SPX2, and a third sub-pixel SPX3. The first sub-pixel SPX1, the second sub-pixel SPX2, and the third sub-pixel SPX3 may include light-emitting diodes corresponding thereto, respectively. The first sub-pixel SPX1 may include a first light-emitting diode LED1. The second sub-pixel SPX2 may include a second light-emitting diode LED2. The third sub-pixel SPX3 may include a third light-emitting diode LED3. The first sub-pixel SPX1, the second sub-pixel SPX2, and the third sub-pixel SPX3 may emit light using their respective light-emitting diodes. The first sub-pixel SPX1, the second sub-pixel SPX2, and the third sub-pixel SPX3 may emit light of different colors from each other. In an embodiment, the first sub-pixel SPX1 may emit a red light through the first light-emitting diode LED1. In an embodiment, the second sub-pixel SPX2 may emit a green light through the second light-emitting diode LED2. In an embodiment, the third sub-pixel SPX3 may emit a blue light through the third light-emitting diode LED3. However, the present disclosure is not limited thereto, and the number of sub-pixels included in a single pixel, and the colors of light emitted from the respective sub-pixels, may be variously modified as needed or desired.

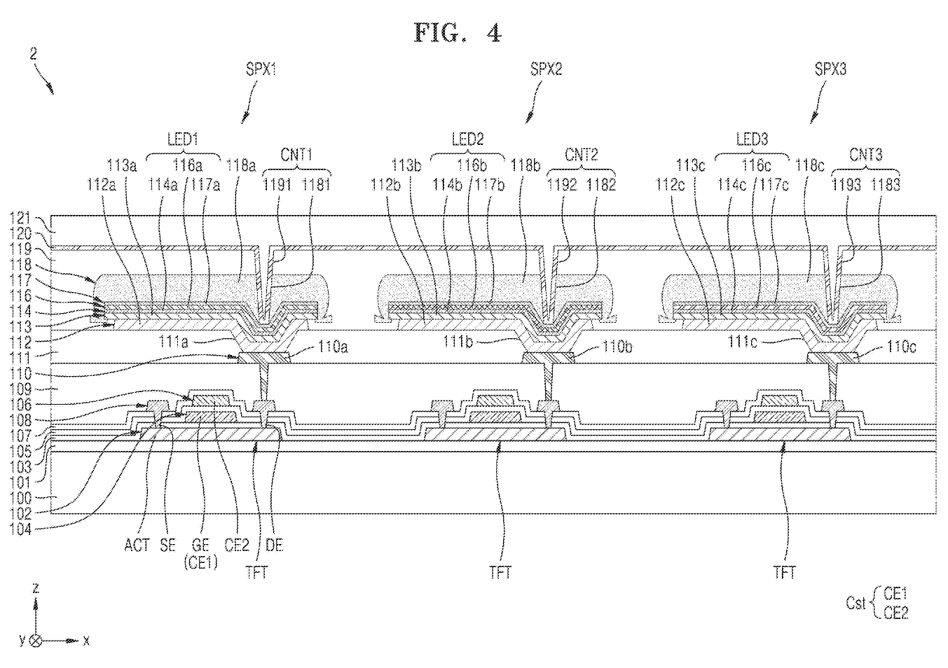

A first connecting portion CNT1 overlapping with the first light-emitting diode LED1 may be provided in the first sub-pixel SPX1. A second connecting portion CNT2 overlapping with the second light-emitting diode LED2 may be provided in the second sub-pixel SPX2. A third connecting portion CNT3 overlapping with the third light-emitting diode LED3 may be provided in the third sub-pixel SPX3. The first connecting portion CNT1 may be provided in the form of an opening defined in (e.g., penetrating) at least one layer arranged on the first light-emitting diode LED1. The second connecting portion CNT2 may be provided in the form of an opening defined in (e.g., penetrating) at least one layer arranged on the second light-emitting diode LED2. The third connecting portion CNT3 may be provided in the form of an opening defined in (e.g., penetrating) at least one layer arranged on the third light-emitting diode LED3. The first connecting portion CNT1, the second connecting portion CNT2, and the third connecting portion CNT3 will be described in more detail below with reference to FIGS. 4 to 7.

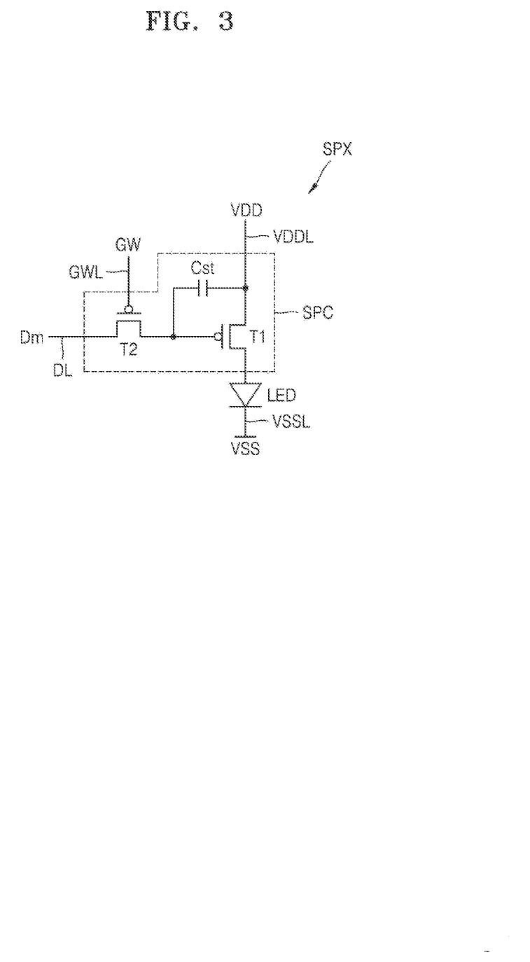

FIG. 3 is a schematic circuit diagram illustrating a light-emitting diode LED and a sub-pixel circuit SPC included in a sub-pixel SPX according to an embodiment.

Referring to FIG. 3, the sub-pixel SPX may be any one of the first sub-pixel SPX1 to the third sub-pixel SPX3 (e.g., see FIG. 2), and the light-emitting diode LED may be any one of the first light-emitting diode LED1 to the third light-emitting diode LED3.

The light-emitting diode LED may be electrically connected to the sub-pixel circuit SPC. The sub-pixel circuit SPC may include a first transistor T1, a second transistor T2, and a storage capacitor Cst. The sub-pixel circuit SPC may be electrically connected to a signal line and a voltage line. The signal line may include a scan signal line GWL and a data line DL. The voltage line may include a first voltage line VDDL.

The second transistor T2 may be a data writing transistor, and may be electrically connected to the scan signal line GWL and the data line DL. The scan signal line GWL may provide a scan signal GW to a gate electrode of the second transistor T2. The second transistor T2 may transmit, to the first transistor T1, a data signal Dm that is input through the data line DL, according to the scan signal GW that is input through the scan signal line GWL.

The storage capacitor Cst may be electrically connected to the second transistor T2 and the first voltage line VDDL, and may store a voltage corresponding to a difference between a voltage from the second transistor T2 and a first power voltage VDD provided through the first voltage line VDDL.

The first transistor T1 may be a driving transistor, and may control a driving current flowing through the light-emitting diode LED. The first transistor T1 may be connected to the first voltage line VDDL and the storage capacitor Cst. The first transistor T1 may control the driving current flowing from the first voltage line VDDL to the light-emitting diode LED according to the voltage stored in the storage capacitor Cst. The light-emitting diode LED may emit light having a desired brightness (e.g., a certain or predetermined brightness) because of the driving current. A first electrode (e.g., a sub-pixel electrode) of the light-emitting diode LED may be electrically connected to the first transistor T1, and a second electrode (e.g., an opposite electrode) of the light-emitting diode LED may be electrically connected to a second voltage line VSSL that provides a second power voltage VSS.

FIG. 3 illustrates that the sub-pixel circuit SPC includes one switching transistor (e.g., the second transistor T2) and one capacitor (e.g., the storage capacitor Cst), but in another embodiment, the sub-pixel circuit SPC may include two or more switching transistors and/or two or more capacitors.

FIG. 4 is a cross-sectional view of the display panel 2 according to an embodiment. FIG. 4 illustrates an embodiment of the display panel 2 taken along the line II-II' of FIG. 2.

Referring to FIG. 4, the first sub-pixel SPX1, the second sub-pixel SPX2, and the third sub-pixel SPX3 may be arranged on a substrate 100. Each of the first sub-pixel SPX1, the second sub-pixel SPX2, and the third sub-pixel SPX3 may include a light-emitting diode, and a thin-film transistor TFT connected to the light-emitting diode. For example, the first sub-pixel SPX1 may include a first light-emitting diode LED1, and a thin-film transistor TFT connected to the first light-emitting diode LED1. The second sub-pixel SPX2 may include a second light-emitting diode LED2, and a thin-film transistor TFT connected to the second light-emitting diode LED2. The third sub-pixel SPX3 may include a third light-emitting diode LED3, and a thin-film transistor TFT connected to the third light-emitting diode LED3. The thin-film transistor TFT may be the first transistor T1 described above with reference to FIG. 3.

A first insulating layer 101 may be arranged on the substrate 100. The first insulating layer 101 may entirely or substantially entirely cover the substrate 100. The first insulating layer 101 may planarize or substantially planarize and protect the upper surface of the substrate 100. The first insulating layer 101 may include an inorganic insulating material. In an embodiment, the first insulating layer 101 may include at least one inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and may have a single-layer structure or a multilayered structure. In an embodiment, the first insulating layer 101 may be a buffer layer.

The thin-film transistor TFT may be arranged on the first insulating layer 101. The thin-film transistor TFT may include an active layer ACT, a gate electrode GE, a source electrode SE, and a drain electrode DE. The thin-film transistors TFT corresponding to the first light-emitting diode LED1 to the third light-emitting diode LED3, respectively, may be arranged on the first insulating layer 101. The structures of the thin-film transistors TFT corresponding to the first light-emitting diode LED1 to the third light-emitting diode LED3, respectively, may be the same or substantially the same as (or similar to) each other.

A semiconductor layer 102 may be arranged on the first insulating layer 101. The semiconductor layer 102 may include the active layer ACT. The active layer ACT may be patterned to correspond to each thin-film transistor TFT. The active layer ACT may include a drain area overlapping with the drain electrode DE, a source area overlapping with the source electrode SE, and a channel area between the drain area and the source area. The drain area and the source area may each be an area that is doped with impurities (e.g., dopants).

A second insulating layer 103 may be arranged on the semiconductor layer 102. The second insulating layer 103 may include an inorganic insulating material. In an embodiment, the second insulating layer 103 may include at least one inorganic insulating material, such as SiO₂, SiNₓ, SiON, Al₂O₃, TiO₂, Ta₂O₅, HfO_{2,} or ZnO₂, and may have a single-layer structure or a multilayered structure. In an embodiment, the second insulating layer 103 may be a gate insulating layer. In an embodiment, as shown in FIG. 4, the second insulating layer 103 may entirely or substantially entirely cover the semiconductor layer 102 and the first insulating layer 101. In an embodiment, the second insulating layer 103 may be patterned to cover (e.g., to only cover) each active layer ACT, and may not cover the upper surface of the first insulating layer 101 between the active layers ACT. In an embodiment, the second insulating layer 103 may be patterned to cover (e.g., to only cover) some portions of each active layer ACT (e.g., a portion overlapping with the gate electrode GE, or in other words, the channel area).

The storage capacitor Cst may be arranged on the second insulating layer 103. The storage capacitor Cst may include a first capacitor electrode CE1 and a second capacitor electrode CE2. The second capacitor electrode CE2 may be arranged on the first capacitor electrode CE1.

A first conductive layer 104 may be arranged on the second insulating layer 103. The first conductive layer 104 may include the gate electrode GE and the first capacitor electrode CE1. The gate electrode GE may be patterned to correspond to each thin-film transistor TFT. The gate electrode GE may overlap with the channel area of the active layer ACT. The first capacitor electrode CE1 may be patterned to correspond to each storage capacitor Cst. In an embodiment, the gate electrode GE and the first capacitor electrode CE1 may be integrally provided with each other, as shown in FIG. 4. In an embodiment, the gate electrode GE and the first capacitor electrode CE1 may each be individually provided. In an embodiment, the first conductive layer 104 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single-layer structure or a multilayered structure.

A third insulating layer 105 may be arranged on the first conductive layer 104. The third insulating layer 105 may entirely or substantially entirely cover the first conductive layer 104. The third insulating layer 105 may include an inorganic insulating material. In an embodiment, the third insulating layer 105 may include at least one inorganic insulating material, such as SiO₂, SiNₓ, SiON, Al₂O₃, TiO₂, Ta₂O₅, HfO_{2,} or ZnO₂, and may have a single-layer structure or a multilayered structure. In an embodiment, the third insulating layer 105 may be a first interlayer insulating layer.

A second conductive layer 106 may be arranged on the third insulating layer 105. The second conductive layer 106 may include the second capacitor electrode CE2 of each storage capacitor Cst. The second capacitor electrode CE2 may be patterned to correspond to each storage capacitor Cst. The second capacitor electrode CE2 may overlap with the first capacitor electrode CE1. In an embodiment, the second conductive layer 106 may include at least one of Al, Pt, Pd, Ag, Mg, Au, Ni, Nd, Ir, Cr, Ca, Mo, Ti, W, and/or Cu, and may have a single-layer structure or a multilayered structure.

A fourth insulating layer 107 may be arranged on the second conductive layer 106. The fourth insulating layer 107 may entirely or substantially entirely cover the second conductive layer 106. The fourth insulating layer 107 may include an inorganic insulating material. In an embodiment, the fourth insulating layer 107 may include at least one inorganic insulating material, such as SiO₂, SiNₓ, SiON, Al₂O₃, TiO₂, Ta₂O₅, HfO_{2,} or ZnO₂, and may have a single-layer structure or a multilayered structure. In an embodiment, the fourth insulating layer 107 may be a second interlayer insulating layer.

A third conductive layer 108 may be arranged on the fourth insulating layer 107. The third conductive layer 108 may include the source electrode SE and the drain electrode DE of each thin-film transistor TFT. The source electrode SE and the drain electrode DE may be patterned to correspond to each thin-film transistor TFT. The source electrode SE may overlap with the source area of the active layer ACT. The drain electrode DE may overlap with the drain area of the active layer ACT. The source electrode SE may be connected to the active layer ACT (e.g., to the source area of the active layer ACT) through an opening defined in (e.g., penetrating) the second insulating layer 103, the third insulating layer 105, and the fourth insulating layer 107. The drain electrode DE may be connected to the active layer ACT (e.g., to the drain area of the active layer ACT) through an opening defined in (e.g., penetrating) the second insulating layer 103, the third insulating layer 105, and the fourth insulating layer 107. In an embodiment, the third conductive layer 108 may include at least one of Al, Pt, Pd, Ag, Mg, Au, Ni, Nd, Ir, Cr, Ca, Mo, Ti, W, and/or Cu, and may have a single-layer structure or a multilayered structure.

A fifth insulating layer 109 may be arranged on the third conductive layer 108. An opening overlapping with the drain electrode DE may be defined in (e.g., may penetrate) the fifth insulating layer 109. The fifth insulating layer 109 may include an organic insulating material. In an embodiment, the fifth insulating layer 109 may include an organic insulating material, for example, such as a general-purpose polymer, such as benzocyclobutene (BCB), polyimide, hexamethyldisiloxane (HMDSO), polymethylmethacrylate (PMMA), or polystyrene, a polymer derivative having a phenol-based group, an acryl-based polymer, an imide-based polymer, an aryl-ether-based polymer, an amide-based polymer, a fluorine-based polymer, a p-xylene-based polymer, or a vinyl alcohol-based polymer, and may have a single-layer structure or a multilayered structure. In an embodiment, the fifth insulating layer 109 may be a first via layer.

A fourth conductive layer 110 may be arranged on the fifth insulating layer 109. The fourth conductive layer 110 may include contact metals respectively corresponding to the first light-emitting diode LED1 to the third light-emitting diode LED3. A first contact metal 110a may correspond to the first light-emitting diode LED1. A second contact metal 110b may correspond to the second light-emitting diode LED2. A third contact metal 110c may correspond to the third light-emitting diode LED3. The first contact metal 110a to the third contact metal 110c may each be connected to a corresponding drain electrode DE through the opening defined in (e.g., penetrating) the fifth insulating layer 109.

A sixth insulating layer 111 may be arranged on the fourth conductive layer 110. A first contact hole 111a overlapping with the first contact metal 110a may be defined in (e.g., may penetrate) the sixth insulating layer 111. A second contact hole 111b overlapping with the second contact metal 110b may be defined in (e.g., may penetrate) the sixth insulating layer 111. A third contact hole 111c overlapping with the third contact metal 110c may be defined in (e.g., may penetrate) the sixth insulating layer 111. In an embodiment, the sixth insulating layer 111 may include an organic insulating material, for example, such as a general-purpose polymer, such as BCB, polyimide, HMDSO, PMMA, or polystyrene, a polymer derivative having a phenol-based group, an acryl-based polymer, an imide-based polymer, an aryl-ether-based polymer, an amide-based polymer, a fluorine-based polymer, a p-xylene-based polymer, or a vinyl alcohol-based polymer, and may have a single-layer structure or a multilayered structure. In an embodiment, the sixth insulating layer 111 may be a second via layer.

A fifth conductive layer 112 may be arranged on the sixth insulating layer 111. The fifth conductive layer 112 may include a 1-1^{st} bank layer 112a corresponding to the first sub-pixel SPX1, a 1-2^{nd} bank layer 112b corresponding to the second sub-pixel SPX2, and a 1-3^{rd} bank layer 112c corresponding to the third sub-pixel SPX3. The 1-1^{st} bank layer 112a, the 1-2^{nd} bank layer 112b, and the 1-3^{rd} bank layer 112c may be spaced apart from each other. The 1-1^{st} bank layer 112a may be connected to (e.g., electrically connected to) the first contact metal 110a through the first contact hole 111a. The 1-2^{nd} bank layer 112b may be connected to (e.g., electrically connected to) the second contact metal 110b through the second contact hole 111b. The 1-3^{rd} bank layer 112c may be connected to (e.g., electrically connected to) the third contact metal 110c through the third contact hole 111c. In an embodiment, the fifth conductive layer 112 may include at least one of Al, Pt, Pd, Ag, Mg, Au, Ni, Nd, Ir, Cr, Ca, Mo, Ti, W, and/or Cu, and may have a single-layer structure or a multilayered structure. In an embodiment, the 1-1^{st} bank layer 112a to the 1-3^{rd} bank layer 112c may each have a single-layer structure including Al.

A sixth conductive layer 113 may be arranged on the fifth conductive layer 112. The sixth conductive layer 113 may include a 2-1^{st} bank layer 113a corresponding to the first sub-pixel SPX1, a 2-2^{nd} bank layer 113b corresponding to the second sub-pixel SPX2, and a 2-3^{rd} bank layer 113c corresponding to the third sub-pixel SPX3. The 2-1^{st} bank layer 113a, the 2-2^{nd} bank layer 113b, and the 2-3^{rd} bank layer 113c may be spaced apart from each other. The 2-1^{st} bank layer 113a may be arranged on the 1-1^{st} bank layer 112a. The 2-1^{st} bank layer 113a may be connected to (e.g., electrically connected to) the 1-1^{st} bank layer 112a through a contact. The 2-2^{nd} bank layer 113b may be arranged on the 1-2^{nd} bank layer 112b. The 2-2^{nd} bank layer 113b may be connected to (e.g., electrically connected to) the 1-2^{nd} bank layer 112b through a contact. The 2-3^{rd} bank layer 113c may be arranged on the 1-3^{rd} bank layer 112c. The 2-3^{rd} bank layer 113c may be connected to (e.g., electrically connected to) the 1-3^{rd} bank layer 112c through a contact. In an embodiment, the sixth conductive layer 113 may include at least one of Al, Pt, Pd, Ag, Mg, Au, Ni, Nd, Ir, Cr, Ca, Mo, Ti, W, and/or Cu, and may have a single-layer structure or a multilayered structure. In an embodiment, the 2-1^{st} bank layer 113a to the 2-3^{rd} bank layer 113c may each have a single-layer structure including Ti.

In an embodiment, the 1-1^{st} bank layer 112a and the 2-1^{st} bank layer 113a may include materials with different etch selectivities from each other. For example, the 1-1^{st} bank layer 112a may include Al, and the 2-1^{st} bank layer 113a may include Ti. In an embodiment, the 1-2^{nd} bank layer 112band the 2-2^{nd} bank layer 113b may include materials with different etch selectivities from each other. For example, the 1-2^{nd} bank layer 112b may include Al, and the 2-2^{nd} bank layer 113b may include Ti. In an embodiment, the 1-3^{rd} bank layer 112c and the 2-3^{rd} bank layer 113c may include materials with different etch selectivities from each other. For example, the 1-3^{rd} bank layer 112c may include Al, and the 2-3^{rd} bank layer 113c may include Ti.

In an embodiment, the 1-1^{st} bank layer 112a and the 2-1^{st} bank layer 113a may together form a tip structure or an undercut structure. For example, a portion of the 2-1^{st} bank layer 113a may extend beyond an edge of the 1-1^{st} bank layer 112a. The portion of the 2-1^{st} bank layer 113a, which extends beyond the edge of the 1-1^{st} bank layer 112a, may be understood as the tip of the 2-1^{st} bank layer 113a. As another example, a portion (e.g., a side surface or an edge) of the 1-1^{st} bank layer 112a may be further recessed compared to a portion (e.g., a side surface or an edge) of the 2-1^{st} bank layer 113a. The structure in which the 1-1^{st} bank layer 112a is recessed may be understood as the undercut structure.

In an embodiment, the 1-2^{nd} bank layer 112b and the 2-2^{nd} bank layer 113b may together form a tip structure or an undercut structure. For example, a portion of the 2-2^{nd} bank layer 113b may extend beyond an edge of the 1-2^{nd} bank layer 112b. The portion of the 2-2^{nd} bank layer 113b, which extends beyond the edge of the 1-2^{nd} bank layer 112b, may be understood as the tip of the 2-2^{nd} bank layer 113b. As another example, a portion (e.g., a side surface or an edge) of the 1-2^{nd} bank layer 112b may be further recessed compared to a portion (e.g., a side surface or an edge) of the 2-2^{nd} bank layer 113b. The structure in which the 1-2^{nd} bank layer 112b is recessed may be understood as the undercut structure.

In an embodiment, the 1-3^{rd} bank layer 112c and the 2-3^{rd} bank layer 113c may together form a tip structure or an undercut structure. For example, a portion of the 2-3^{rd} bank layer 113c may extend beyond an edge of the 1-3^{rd} bank layer 112c. The portion of the 2-3^{rd} bank layer 113c, which extends beyond the edge of the 1-3^{rd} bank layer 112c, may be understood as a tip of the 2-3^{rd} bank layer 113c. As another example, a portion (e.g., a side surface or an edge) of the 1-3^{rd} bank layer 112c may be further recessed compared to a portion (e.g., a side surface or an edge) of the 2-3^{rd} bank layer 113c. The structure in which the 1-3^{rd} bank layer 112c is recessed may be understood as the undercut structure.

In an embodiment, shapes and/or dimensions of the tip structures (or undercut structures) of the 1-1^{st} bank layer 112a and the 2-1^{st} bank layer 113a, the tip structures (or undercut structures) of the 1-2^{nd} bank layer 112b and the 2-2^{nd} bank layer 113b, and the tip structures (or undercut structures) of the 1-3^{rd} bank layer 112c and the 2-3^{rd} bank layer 113c may be the same or substantially the same as (or similar to) each other.

The first light-emitting diode LED1 may be arranged on the 2-1^{st} bank layer 113a. The first light-emitting diode LED1 may include a first sub-pixel electrode 114a, a first intermediate layer 116a, and a first opposite electrode 117a. The second light-emitting diode LED2 may be arranged on the 2-2^{nd} bank layer 113b. The second light-emitting diode LED2 may include a second sub-pixel electrode 114b, a second intermediate layer 116b, and a second opposite electrode 117b. The third light-emitting diode LED3 may be arranged on the 2-3^{rd} bank layer 113c. The third light-emitting diode LED3 may include a third sub-pixel electrode 114c, a third intermediate layer 116c, and a third opposite electrode 117c.

A seventh conductive layer 114 may be arranged on the sixth conductive layer 113. The seventh conductive layer 114 may include the first sub-pixel electrode 114a, the second sub-pixel electrode 114b, and the third sub-pixel electrode 114c. The first sub-pixel electrode 114a, the second sub-pixel electrode 114b, and the third sub-pixel electrode 114c may be individually patterned, and may be spaced apart from each other. In an embodiment, the seventh conductive layer 114 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the seventh conductive layer 114 may include a reflective layer including Ag, Mg, Al, Pt, Pd, Au, Ni, Nd, Ir, Cr, or a suitable compound thereof. The structure and the materials of the seventh conductive layer 114 are not limited thereto, and may be variously modified as needed or desired.

The first sub-pixel electrode 114a may be arranged on the 2-1^{st} bank layer 113a. The first sub-pixel electrode 114a may be connected to (e.g., electrically connected to) the 2-1^{st} bank layer 113a through a contact. Therefore, the first sub-pixel electrode 114a may be connected to the thin-film transistor TFT (e.g., the active layer ACT of the thin-film transistor TFT) through the 2-1^{st} bank layer 113a, the 1-1^{st}bank layer 112a, the first contact metal 110a, and the drain electrode DE. As such, the first power voltage VDD (e.g., see FIG. 3) may be applied to the first sub-pixel electrode 114a.

The second sub-pixel electrode 114b may be arranged on the 2-2^{nd} bank layer 113b. The second sub-pixel electrode 114b may be connected to (e.g., electrically connected to) the 2-2^{nd} bank layer 113b through a contact. Therefore, the second sub-pixel electrode 114b may be connected to the thin-film transistor TFT (e.g., the active layer ACT of the thin-film transistor TFT) through the 2-2^{nd} bank layer 113b, the 1-2^{nd} bank layer 112b, the second contact metal 110b, and the drain electrode DE. As such, the first power voltage VDD (e.g., see FIG. 3) may be applied to the second sub-pixel electrode 114b.

The third sub-pixel electrode 114c may be arranged on the 2-3^{rd} bank layer 113c. The third sub-pixel electrode 114c may be connected to (e.g., electrically connected to) the 2-3^{rd} bank layer 113c through a contact. Therefore, the third sub-pixel electrode 114c may be connected to the thin-film transistor TFT (e.g., the active layer ACT of the thin-film transistor TFT) through the 2-3^{rd} bank layer 113c, the 1-3^{rd} bank layer 112c, the third contact metal 110c, and the drain electrode DE. As such, the first power voltage VDD (e.g., see FIG. 3) may be applied to the third sub-pixel electrode 114c.

An intermediate layer 116 may be arranged on the seventh conductive layer 114. The intermediate layer 116 may include the first intermediate layer 116a, the second intermediate layer 116b, and the third intermediate layer 116c. The first intermediate layer 116a, the second intermediate layer 116b, and the third intermediate layer 116c may be individually patterned, and may be spaced apart from each other. The first intermediate layer 116a may be arranged on the first sub-pixel electrode 114a. The second intermediate layer 116b may be arranged on the second sub-pixel electrode 114b. The third intermediate layer 116c may be arranged on the third sub-pixel electrode 114c.

In an embodiment, the intermediate layer 116 may include an emission layer and a functional layer. The emission layer may include a low-molecular-weight material or a high-molecular-weight material emitting light when a voltage (e.g., a specific or predetermined voltage) is applied (or when a specific or predetermined current flows). The functional layer may include at least one of an Electron Transport Layer (ETL), an Electron Injection Layer (EIL), a Hole Transport Layer (HTL), or a Hole Injection Layer (HIL). The first intermediate layer 116a, the second intermediate layer 116b, and the third intermediate layer 116c may each include an emission layer and a functional layer.

In an embodiment, the emission layers of the first intermediate layer 116a, the second intermediate layer 116b, and the third intermediate layer 116c may include different materials from each other. In other words, the emission layers of the first intermediate layer 116a, the second intermediate layer 116b, and the third intermediate layer 116c may emit light in different wavelength bands or colors from each other. In an embodiment, the emission layer included in the first intermediate layer 116a may emit a red light when a voltage (e.g., a specific or predetermined voltage) is applied. In an embodiment, the emission layer included in the second intermediate layer 116b may emit a green light when a voltage (e.g., a specific or predetermined voltage) is applied. In an embodiment, the emission layer included in the third intermediate layer 116c may emit a blue light when a voltage (e.g., a specific or predetermined voltage) is applied.

An eighth conductive layer 117 may be arranged on the intermediate layer 116. The eighth conductive layer 117 may include the first opposite electrode 117a, the second opposite electrode 117b, and the third opposite electrode 117c. The first opposite electrode 117a, the second opposite electrode 117b, and the third opposite electrode 117c may be individually patterned, and may be spaced apart from each other. The first opposite electrode 117a may be arranged on the first intermediate layer 116a. The second opposite electrode 117b may be arranged on the second intermediate layer 116b. The third opposite electrode 117c may be arranged on the third intermediate layer 116c.

The eighth conductive layer 117 may include a conductive material having a low work function. For example, the eighth conductive layer 117 may include a transparent (or translucent) layer including Ag, Mg, Al, Pt, Pd, Au, Ni, Nd, Ir, Cr, Li, Ca, or a suitable alloy thereof. As another example, the eighth conductive layer 117 may further include a layer including ITO, IZO, ZnO, or In₂O₃ on the transparent (or translucent) layer including one or more of the aforementioned materials.

A first encapsulation layer 118 may be arranged on the eighth conductive layer 117. The first encapsulation layer 118 may include a 1-1^{st} encapsulation layer 118a, a 1-2^{nd} encapsulation layer 118b, and a 1-3^{rd} encapsulation layer 118c. The first encapsulation layer 118 may include an inorganic insulating material. In an embodiment, the first encapsulation layer 118 may include at least one inorganic insulating material, such as SiO₂, SiNₓ, SiON, Al₂O₃, TiO₂, Ta₂O₅, HfO₂, or ZnO₂. In other words, in the present embodiment, the first encapsulation layer 118 may be implemented as an inorganic encapsulation layer. In an embodiment, the first encapsulation layer 118 may be formed through Chemical Vapor Deposition (CVD).

The 1-1^{st} encapsulation layer 118a may be arranged on the first opposite electrode 117a. The 1-1^{st} encapsulation layer 118a may entirely or substantially entirely cover the first light-emitting diode LED1. For example, the 1-1^{st} encapsulation layer 118a may cover the upper surface and side surfaces of the first opposite electrode 117a, the side surfaces of the first intermediate layer 116a, and the side surfaces of the first sub-pixel electrode 114a. The 1-1^{st} encapsulation layer 118a may cover the edges and side surfaces of the 2-1^{st} bank layer 113a (e.g., the edges and side surfaces of the tip). The 1-1^{st} encapsulation layer 118a may partially cover the lower surface of the 2-1^{st} bank layer 113a (e.g., the lower surface of the tip). The 1-1^{st} encapsulation layer 118a may be spaced apart from the 1-1^{st} bank layer 112a (e.g., the side surfaces of the 1-1^{st} bank layer 112a).

The 1-2^{nd} encapsulation layer 118b may be arranged on the second opposite electrode 117b. The 1-2^{nd} encapsulation layer 118b may entirely or substantially entirely cover the second light-emitting diode LED2. For example, the 1-2^{nd} encapsulation layer 118b may cover the upper surface and side surfaces of the second opposite electrode 117b, the side surfaces of the second intermediate layer 116b, and the side surfaces of the second sub-pixel electrode 114b. The 1-2^{nd} encapsulation layer 118b may cover the edges and side surfaces of the 2-2^{nd} bank layer 113b (e.g., the edges and side surfaces of the tip). The 1-2^{nd} encapsulation layer 118b may partially cover the lower surface of the 2-2^{nd} bank layer 113b (e.g., the lower surface of the tip). The 1-2^{nd} encapsulation layer 118b may be spaced apart from the 1-2^{nd} bank layer 112b (e.g., the side surfaces of the 1-2^{nd} bank layer 112b).

The 1-3^{rd} encapsulation layer 118c may be arranged on the third opposite electrode 117c. The 1-3^{rd} encapsulation layer 118c may entirely or substantially entirely cover the third light-emitting diode LED3. For example, the 1-3^{rd} encapsulation layer 118c may cover the upper surface and side surfaces of the third opposite electrode 117c, the side surfaces of the third intermediate layer 116c, and the side surfaces of the third sub-pixel electrode 114c. The 1-3^{rd} encapsulation layer 118c may cover the edges and side surfaces of the 2-3^{rd} bank layer 113c (e.g., the edges and side surfaces of the tip). The 1-3^{rd} encapsulation layer 118c may partially cover the lower surface of the 2-3^{rd} bank layer 113c (e.g., the lower surface of the tip). The 1-3^{rd} encapsulation layer 118c may be spaced apart from the 1-3^{rd} bank layer 112c (e.g., the side surfaces of the 1-3^{rd} bank layer 112c).

A second encapsulation layer 119 may be arranged on the first encapsulation layer 118. The second encapsulation layer 119 may entirely or substantially entirely cover the first encapsulation layer 118. For example, the second encapsulation layer 119 may cover the 1-1^{st} encapsulation layer 118a, the 1-2^{nd} encapsulation layer 118b, and the 1-3^{rd} encapsulation layer 118c. In an embodiment, the second encapsulation layer 119 may include an organic insulating material. For example, the second encapsulation layer 119 may include a polymer-based material. Examples of the polymer-based material may include a silicon-based resin, an acrylic resin, an epoxy-based resin, polyimide, polyethylene, and the like. In other words, in the present embodiment, the second encapsulation layer 119 may be implemented as an organic encapsulation layer. Accordingly, the second encapsulation layer 119 may have a flat or substantially flat upper surface.

The second encapsulation layer 119 may fill a gap between the 1-1^{st} encapsulation layer 118a and the 1-2^{nd} encapsulation layer 118b. The second encapsulation layer 119 may fill a gap between the 1-2^{nd} encapsulation layer 118b and the 1-3^{rd} encapsulation layer 118c. The second encapsulation layer 119 may fill a gap between the 1-1^{st} encapsulation layer 118a and the 1-1^{st} bank layer 112a (e.g., the side surfaces of the 1-1^{st} bank layer 112a), and may cover the side surfaces of the 1-1^{st} bank layer 112a. The second encapsulation layer 119 may fill the gap between the 1-2^{nd} encapsulation layer 118b and the 1-2^{nd} bank layer 112b (e.g., the side surfaces of the 1-2^{nd} bank layer 112b), and may cover the side surfaces of the 1-2^{nd} bank layer 112b. The second encapsulation layer 119 may fill the gap between the 1-3^{rd} encapsulation layer 118c and the 1-3^{rd} bank layer 112c (e.g., the side surfaces of the 1-3^{rd} bank layer 112c), and may cover the side surfaces of the 1-3^{rd} bank layer 112c.

The first connecting portion CNT1 may include a 1-1^{st} connecting opening 1181 and a 2-1^{st} connecting opening 1191. The 1-1^{st} connecting opening 1181 may be defined in (e.g., may penetrate) the first encapsulation layer 118, for example, the 1-1^{st} encapsulation layer 118a. The 1-1^{st} connecting opening 1181 may penetrate the 1-1^{st} encapsulation layer 118a. A portion of the upper surface of the first opposite electrode 117a may be exposed through the 1-1^{st} connecting opening 1181. The 2-1^{st} connecting opening 1191 may be defined in (e.g., may penetrate) the second encapsulation layer 119. The 2-1^{st} connecting opening 1191 may penetrate the second encapsulation layer 119. The 1-1^{st} connecting opening 1181 may overlap with and be connected to the 2-1^{st} connecting opening 1191. In an embodiment, the 1-1^{st} connecting opening 1181 and the 2-1^{st} connecting opening 1191 may overlap with the first contact hole 111a and the first contact metal 110a.

The second connecting portion CNT2 may include a 1-2^{nd} connecting opening 1182 and a 2-2^{nd} connecting opening 1192. The 1-2^{nd} connecting opening 1182 may be defined in (e.g., may penetrate) the first encapsulation layer 118, for example, the 1-2^{nd} encapsulation layer 118b. The 1-2^{nd} connecting opening 1182 may penetrate the 1-2^{nd} encapsulation layer 118b. A portion of the upper surface of the second opposite electrode 117b may be exposed through the 1-2^{nd} connecting opening 1182. The 2-2^{nd} connecting opening 1192 may be defined in (e.g., may penetrate) the second encapsulation layer 119. The 2-2^{nd} connecting opening 1192 may penetrate the second encapsulation layer 119. The 1-2^{nd} connecting opening 1182 and the 2-2^{nd} connecting opening 1192 may overlap with and be connected to each other. In an embodiment, the 1-2^{nd} connecting opening 1182 and the 2-2^{nd} connecting opening 1192 may overlap with the second contact hole 111b and the second contact metal 110b.

The third connecting portion CNT3 may include a 1-3^{rd} connecting opening 1183 and a 2-3^{rd} connecting opening 1193. The 1-3^{rd} connecting opening 1183 may be defined in (e.g., may penetrate) the first encapsulation layer 118, for example, the 1-3^{rd} encapsulation layer 118c. The 1-3^{rd} connecting opening 1183 may penetrate the 1-3^{rd} encapsulation layer 118c. A portion of the upper surface of the third opposite electrode 117c may be exposed through the 1-3^{rd} connecting opening 1183. The 2-3^{rd} connecting opening 1193 may be defined in (e.g., may penetrate) the second encapsulation layer 119. The 2-3^{rd} connecting opening 1193 may penetrate the second encapsulation layer 119. The 1-3^{rd} connecting opening 1183 and the 2-3^{rd} connecting opening 1193 may overlap with and be connected to each other. In an embodiment, the 1-3^{rd} connecting opening 1183 and the 2-3^{rd} connecting opening 1193 may overlap with the third contact hole 111c and the third contact metal 110c.

An upper electrode 120 may be arranged on the second encapsulation layer 119. The upper electrode 120 may include a conductive material. In an embodiment, the upper electrode 120 may include a conductive oxide (e.g., a transparent or translucent conductive oxide), such as ITO, IZO, ZnO, In₂O₃, IGO, or AZO. In an embodiment, the upper electrode 120 may include a metal, such as Ag, Mg, Al, Pt, Pd, Au, Ni, Nd, Ir, or Cr.

The upper electrode 120 may be connected to the first opposite electrode 117a through the first connecting portion CNT1. For example, a portion of the upper electrode 120 may be arranged in the 1-1^{st} connecting opening 1181 and the 2-1^{st} connecting opening 1191, and may directly contact the upper surface of the first opposite electrode 117a. In the present embodiment, because the first connecting portion CNT1 may overlap with the first contact hole 111a and the first contact metal 110a, an area where the upper electrode 120 contacts the first opposite electrode 117a may also overlap with the first contact hole 111a and the first contact metal 110a.

The upper electrode 120 may be connected to the second opposite electrode 117b through the second connecting portion CNT2. For example, a portion of the upper electrode 120 may be arranged in the 1-2^{nd} connecting opening 1182 and the 2-2^{nd} connecting opening 1192, and may directly contact the upper surface of the second opposite electrode 117b. In the present embodiment, because the second connecting portion CNT2 may overlap with the second contact hole 111b and the second contact metal 110b, an area where the upper electrode 120 contacts the second opposite electrode 117b may also overlap with the second contact hole 111b and the second contact metal 110b.

The upper electrode 120 may be connected to the third opposite electrode 117c through the third connecting portion CNT3. For example, a portion of the upper electrode 120 may be arranged in the 1-3^{rd} connecting opening 1183 and the 2-3^{rd} connecting opening 1193, and may directly contact the upper surface of the third opposite electrode 117c. In the present embodiment, because the third connecting portion CNT3 may overlap with the third contact hole 111c and the third contact metal 110c, an area where the upper electrode 120 contacts the third opposite electrode 117c may also overlap with the third contact hole 111c and the third contact metal 110c.

In an embodiment, referring to FIGS. 1 and 3 together, the upper electrode 120 may be electrically connected to the second voltage line VSSL. For example, a portion of the upper electrode 120 may extend to the peripheral area PA beyond the display area DA, and may be connected to the second voltage line VSSL in the peripheral area PA. As such, the second power voltage VSS may be provided to the upper electrode 120, and may also be provided to the first opposite electrode 117a to the third opposite electrode 117c.

A third encapsulation layer 121 may be arranged on the upper electrode 120. The third encapsulation layer 121 may entirely or substantially entirely cover the upper electrode 120. A portion of the third encapsulation layer 121 may be arranged in the first connecting portion CNT1, the second connecting portion CNT2, or the third connecting portion CNT3. The third encapsulation layer 121 may have a single-layer structure or a multilayered structure. In an embodiment, the third encapsulation layer 121 may include at least one inorganic encapsulation layer including an inorganic insulating material and/or at least one organic encapsulation layer including an organic insulating material. In an embodiment, the third encapsulation layer 121 may include an inorganic encapsulation layer arranged on the upper electrode 120, and an organic encapsulation layer arranged on the inorganic encapsulation layer. In an embodiment, the third encapsulation layer 121 may include a first inorganic encapsulation layer arranged on the upper electrode 120, an organic encapsulation layer arranged on the first inorganic encapsulation layer, and a second inorganic encapsulation layer arranged on the organic encapsulation layer. However, the present disclosure is not limited thereto, and the materials and the structure of the third encapsulation layer 121 may be variously modified as needed or desired.

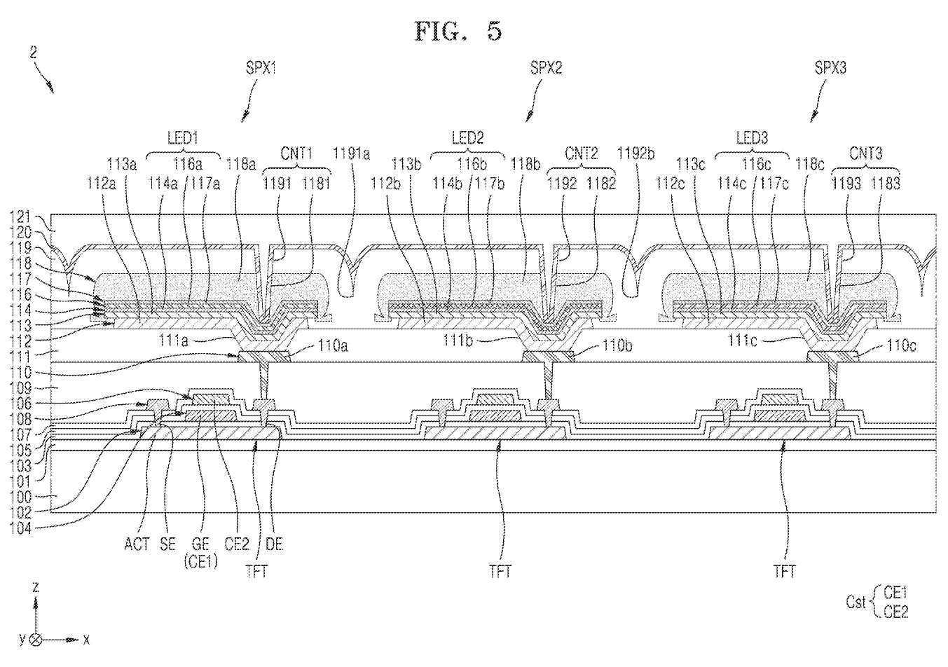

FIG. 5 is a cross-sectional view of the display panel 2 according to an embodiment. FIG. 5 illustrates an embodiment of the display panel 2 taken along the line II-II' of FIG. 2.

Referring to FIG. 5, the second encapsulation layer 119 may be implemented as an inorganic encapsulation layer. In an embodiment, the second encapsulation layer 119 may include at least one inorganic insulating material, such as SiO₂, SiNₓ, SiON, Al₂O₃, TiO₂, Ta₂O₅, HfO₂, or ZnO₂. In an embodiment, the second encapsulation layer 119 may be formed through CVD.

Accordingly, the shape of a portion of the second encapsulation layer 119 may be the same or substantially the same as (or similar to) that of the first encapsulation layer 118. For example, the second encapsulation layer 119 may include a first indentation 1191a arranged between the 1-1^{st} encapsulation layer 118a and the 1-2^{nd} encapsulation layer 118b. Similarly, the second encapsulation layer 119 may include a second indentation 1192b arranged between the 1-2^{nd} encapsulation layer 118b and the 1-3^{rd} encapsulation layer 118c.

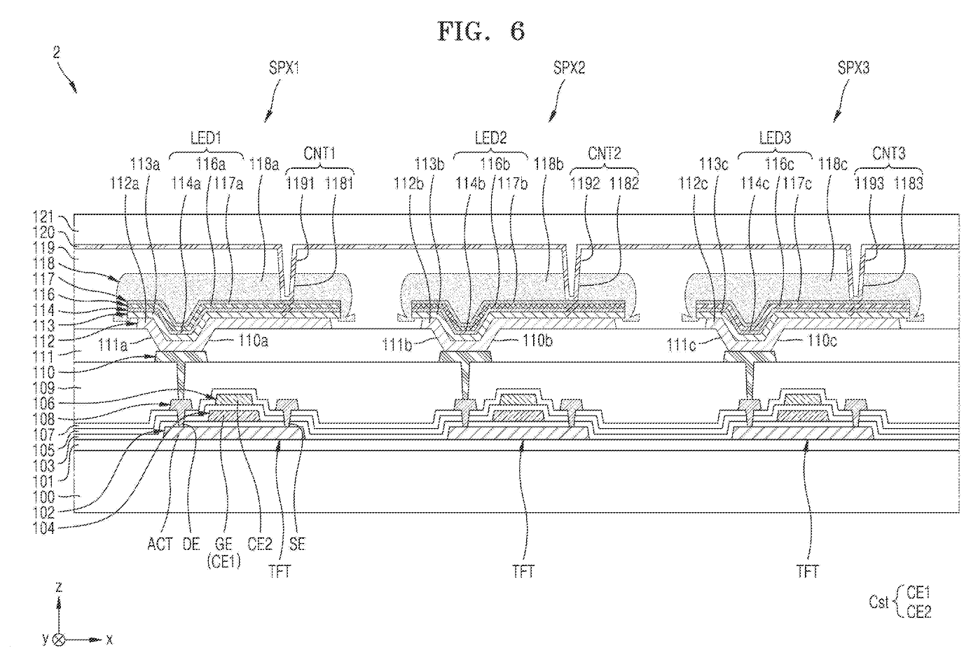

FIG. 6 is a cross-sectional view of the display panel 2 according to an embodiment. FIG. 6 illustrates an embodiment of the display panel 2 taken along the line II-II' of FIG. 2.

Referring to FIG. 6, the first connecting portion CNT1 may not overlap with the first contact hole 111a or the first contact metal 110a. For example, the 1-1^{st} connecting opening 1181 and the 2-1^{st} connecting opening 1191 may not overlap with the first contact hole 111a or the first contact metal 110a. A portion of the upper electrode 120 arranged on the first connecting portion CNT1 may not overlap with the first contact hole 111a or the first contact metal 110a as well. Similarly, the second connecting portion CNT2 may not overlap with the second contact hole 111b or the second contact metal 110b. For example, the 1-2^{nd} connecting opening 1182 and the 2-2^{nd} connecting opening 1192 may not overlap with the second contact hole 111b or the second contact metal 110b. A portion of the upper electrode 120 arranged on the second connecting portion CNT2 may not overlap with the second contact hole 111b or the second contact metal 110b as well. Similarly, the third connecting portion CNT3 may not overlap with the third contact hole 111c or the third contact metal 110c. For example, the 1-3^{rd} connecting opening 1183 and the 2-3^{rd} connecting opening 1193 may not overlap with the third contact hole 111c or the third contact metal 110c. A portion of the upper electrode 120 arranged on the third connecting portion CNT3 may not overlap with the third contact hole 111c or the third contact metal 110c as well.

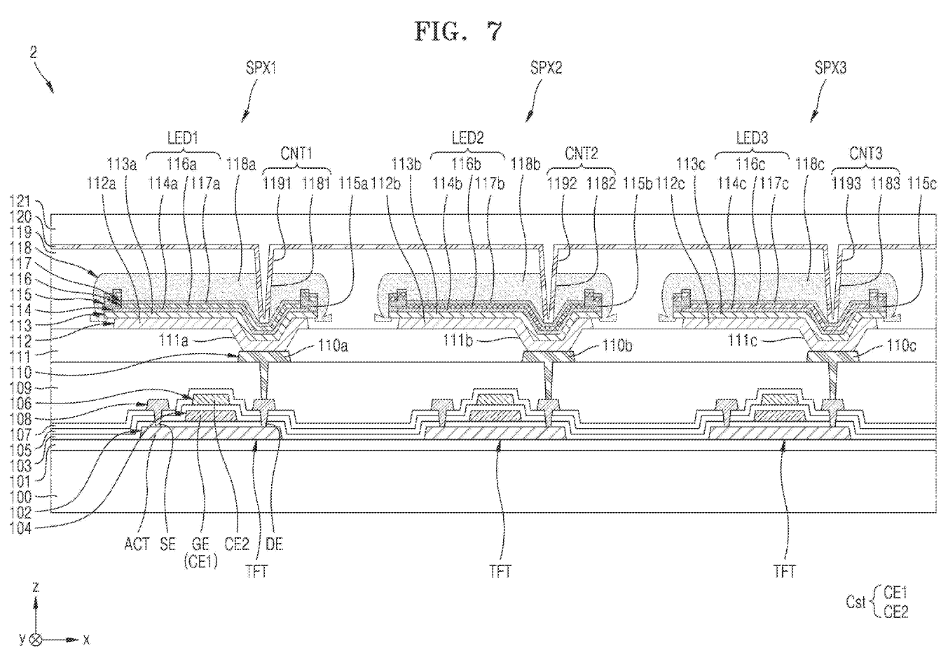

FIG. 7 is a cross-sectional view of the display panel 2 according to an embodiment. FIG. 7 illustrates an embodiment of the display panel 2 taken along the line II-II' of FIG. 2.

Referring to FIG. 7, the display panel 2 may further include a seventh insulating layer 115. The seventh insulating layer 115 may be arranged on the seventh conductive layer 114. For example, the seventh insulating layer 115 may be arranged between the seventh conductive layer 114 and the intermediate layer 116. The seventh insulating layer 115 may include an inorganic insulating material. In an embodiment, the seventh insulating layer 115 may include at least one inorganic insulating material, such as SiO₂, SiNₓ, SiON, Al₂O₃, TiO₂, Ta₂O₅, HfO_{2,} or ZnO₂, and may have a single-layer structure or a multilayered structure. In an embodiment, the seventh insulating layer 115 may have a single-layer structure including SiNₓ.

The seventh insulating layer 115 may include a first protective layer 115a, a second protective layer 115b, and a third protective layer 115c. The first protective layer 115a may be arranged on the 2-1^{st} bank layer 113a and the first sub-pixel electrode 114a. The first protective layer 115a may cover an edge region (e.g., an edge) of the first sub-pixel electrode 114a. The second protective layer 115b may be arranged on the 2-2^{nd} bank layer 113b and the second sub-pixel electrode 114b. The second protective layer 115b may cover an edge region (e.g., an edge) of the second sub-pixel electrode 114b. The third protective layer 115c may be arranged on the 2-3^{rd} bank layer 113c and the third sub-pixel electrode 114c. The third protective layer 115c may cover an edge region (e.g., an edge) of the third sub-pixel electrode 114c.

A portion of the intermediate layer 116 may be arranged on the seventh conductive layer 114, and another portion of the intermediate layer 116 may be arranged on the seventh insulating layer 115. In an embodiment, a portion of the first intermediate layer 116a may be arranged on the first sub-pixel electrode 114a, and another portion of the first intermediate layer 116a may be arranged on the first protective layer 115a. A portion of the first intermediate layer 116a arranged on the first protective layer 115a may be understood as a dummy intermediate layer. In an embodiment, a portion of the second intermediate layer 116b may be arranged on the second sub-pixel electrode 114b, and another portion of the second intermediate layer 116b may be arranged on the second protective layer 115b. A portion of the second intermediate layer 116b arranged on the second protective layer 115b may be understood as a dummy intermediate layer. In an embodiment, a portion of the third intermediate layer 116c may be arranged on the third sub-pixel electrode 114c, and another portion of the third intermediate layer 116c may be arranged on the third protective layer 115c. A portion of the third intermediate layer 116c arranged on the third protective layer 115c may be understood as a dummy intermediate layer.

Similarly, a portion of the eighth conductive layer 117 may be arranged on the seventh conductive layer 114, and another portion of the eighth conductive layer 117 may be arranged on the seventh insulating layer 115. In an embodiment, a portion of the first opposite electrode 117a may be arranged on the first sub-pixel electrode 114a, and another portion of the first opposite electrode 117a may be arranged on the first protective layer 115a. A portion of the first opposite electrode 117a arranged on the first protective layer 115a may be understood as a dummy opposite electrode. In an embodiment, a portion of the second opposite electrode 117b may be arranged on the second sub-pixel electrode 114b, and another portion of the second opposite electrode 117b may be arranged on the second protective layer 115b. A portion of the second opposite electrode 117b arranged on the second protective layer 115b may be understood as a dummy opposite electrode. In an embodiment, a portion of the third opposite electrode 117c may be arranged on the third sub-pixel electrode 114c, and another portion of the third opposite electrode 117c may be arranged on the third protective layer 115c. A portion of the third opposite electrode 117c arranged on the third protective layer 115c may be understood as a dummy opposite electrode.

The first encapsulation layer 118 may cover the seventh insulating layer 115 together with the first light-emitting diode LED1 to the third light-emitting diode LED3. For example, the 1-1^{st} encapsulation layer 118a may cover the first light-emitting diode LED1 and the first protective layer 115a. Similarly, the 1-2^{nd} encapsulation layer 118b may cover the second light-emitting diode LED2 and the second protective layer 115b. Similarly, the 1-3^{rd} encapsulation layer 118c may cover the third light-emitting diode LED3 and the third protective layer 115c.

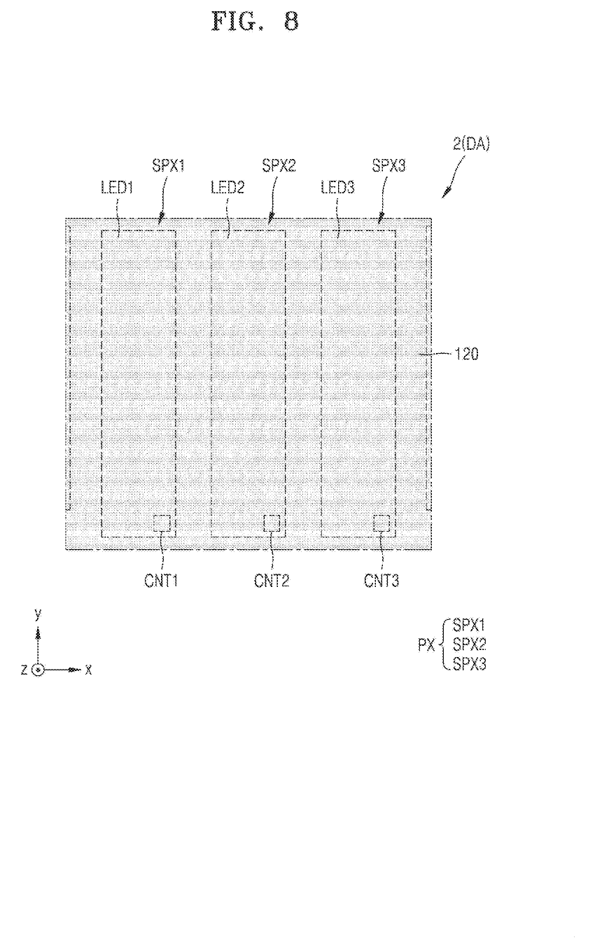

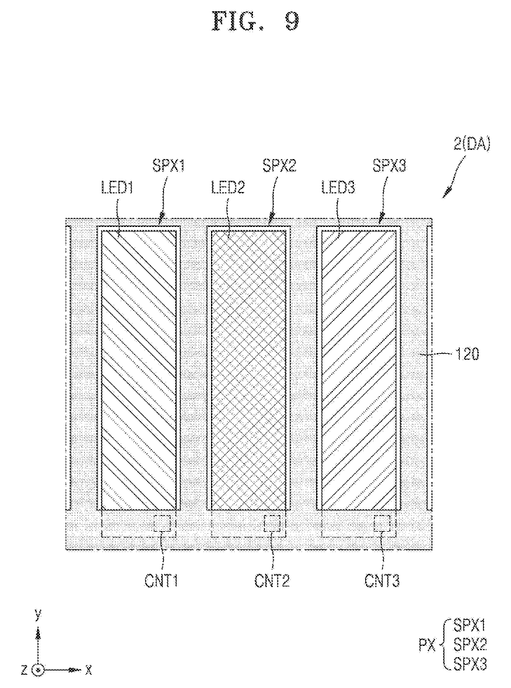

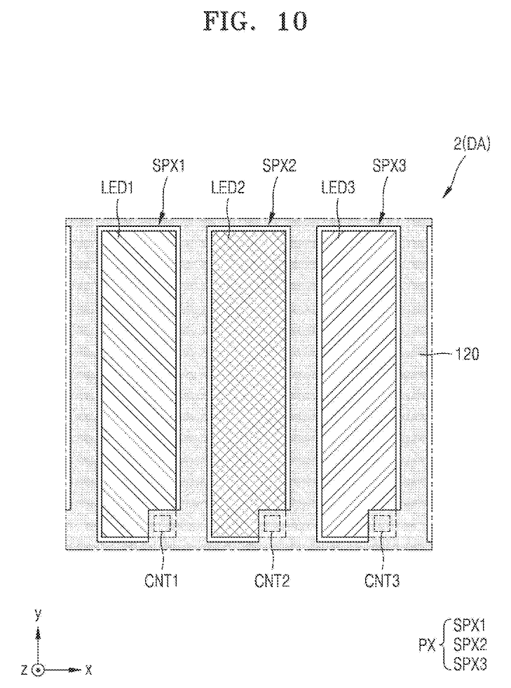

FIG. 8 is a plan view of a portion of the display panel 2 according to an embodiment. FIG. 9 is a plan view of a portion of the display panel 2 according to an embodiment. FIG. 10 is a plan view of a portion of the display panel 2 according to an embodiment.

Referring to FIGS. 8 to 10, the upper electrode 120 may cover the first connecting portion CNT1 to the third connecting portion CNT3. The upper electrode 120 may at least partially cover the first light-emitting diode LED1 to the third light-emitting diode LED3.

In an embodiment, as shown in FIG. 8, the upper electrode 120 may entirely or substantially entirely cover the first light-emitting diode LED1 to the third light-emitting diode LED3. In the present embodiment, the upper electrode 120 may include, for example, a transparent conductive oxide, to allow the transmission of light emitted from the first light-emitting diode LED1 to the third light-emitting diode LED3.

In an embodiment, as shown in FIGS. 9 and 10, the upper electrode 120 may partially cover each of the first light-emitting diode LED1 to the third light-emitting diode LED3. In other words, the upper electrode 120 may include openings overlapping with the first light-emitting diode LED1 to the third light-emitting diode LED3, respectively. In other words, the upper electrode 120 may have a mesh structure including the openings that overlap with the first light-emitting diode LED1 to the third light-emitting diode LED3, respectively. In the present embodiment, the upper electrode 120 may include a light-transmissive material (e.g., a transparent conductive oxide) or a non-light-transmissive material (e.g., a metal).

In an embodiment, as shown in FIG. 9, the upper electrode 120 may extend along the x axis in areas where the upper electrode 120 overlaps with the first connecting portion CNT1, the second connecting portion CNT2, or the third connecting portion CNT3, and may cover a portion of each of the first light-emitting diode LED1 to the third light-emitting diode LED3.

In an embodiment, as shown in FIG. 10, the upper electrode 120 may cover (e.g., may only cover) the first connecting portion CNT1 to the third connecting portion CNT3, and may not cover other portions of the first light-emitting diode LED1 to the third light-emitting diode LED3. In other words, in the present embodiment, the upper electrode 120 may have a mesh structure including a portion protruding to cover the first connecting portion CNT1, the second connecting portion CNT2, or the third connecting portion CNT3.

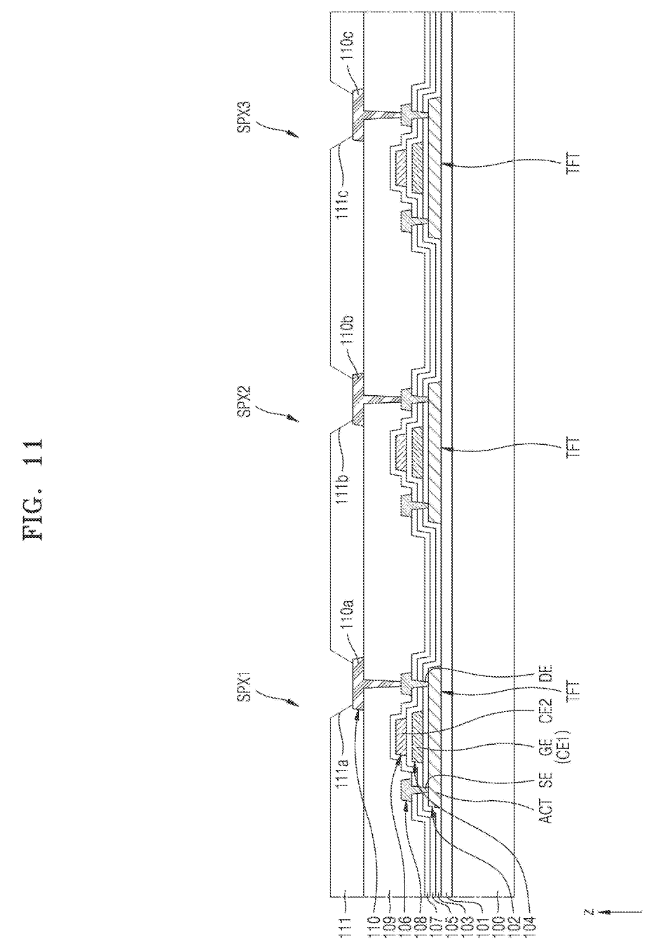

FIGS. 11 through 28 are cross-sectional views illustrating some operations of a method of manufacturing a display panel according to some embodiments. Hereinafter, for convenience of illustration, the method described in more detail with reference to FIGS. 11 to 28 may correspond to (e.g., may be) a method of manufacturing the display panel 2 described above with reference to FIG. 7. However, the present disclosure is not limited thereto. The display panels 2 described above with reference to FIGS. 4 to 6 may also be manufactured by omitting, adding, or modifying some of the operations described in more detail hereinafter with reference to FIGS. 11 to 28.

Referring to FIG. 11, the fourth conductive layer 110 and the sixth insulating layer 111 may be arranged on the fifth insulating layer 109. The fourth conductive layer 110 may include the first contact metal 110a, the second contact metal 110b, and the third contact metal 110c, which are arranged to be spaced apart from each other. The first contact metal 110a, the second contact metal 110b, and the third contact metal 110c may be patterned to be spaced apart from each other.

The sixth insulating layer 111 may be arranged on the fourth conductive layer 110. The sixth insulating layer 111 may cover the edge region (e.g., the edge) of each of the first contact metal 110a, the second contact metal 110b, and the third contact metal 110c. In other words, the sixth insulating layer 111 may have openings that expose the central portions of the first contact metal 110a, the second contact metal 110b, and the third contact metal 110c, respectively. In an embodiment, the sixth insulating layer 111 may be formed by arranging an insulating layer to entirely or substantially entirely cover the first contact metal 110a, the second contact metal 110b, and the third contact metal 110c, and then etching the insulating layer to form the first contact hole 111a, the second contact hole 111b, and the third contact hole 111c.

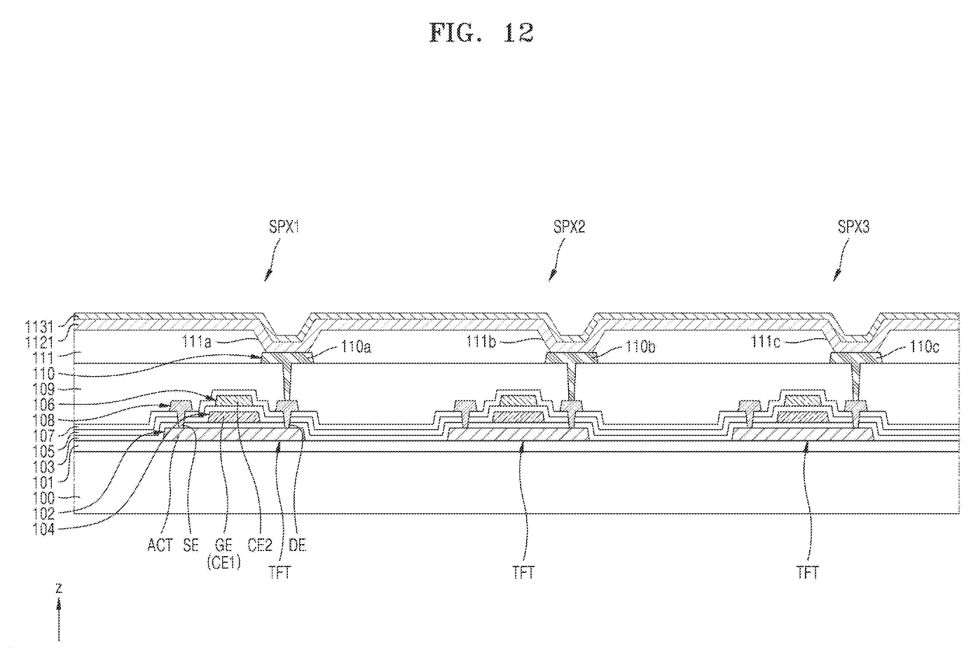

Referring to FIG. 12, a first material layer 1121 and a second material layer 1131 may be arranged on the sixth insulating layer 111. The first material layer 1121 may entirely or substantially entirely cover the sixth insulating layer 111. The first material layer 1121 may contact the first contact metal 110a to the third contact metal 110c through the first contact hole 111a to the third contact hole 111c, respectively. The second material layer 1131 may entirely or substantially entirely cover the first material layer 1121.

The first material layer 1121 may include a conductive material. In an embodiment, the first material layer 1121 may include at least one of Al, Pt, Pd, Ag, Mg, Au, Ni, Nd, Ir, Cr, Ca, Mo, Ti, W, and/or Cu, and may have a single-layer structure or a multilayered structure. In an embodiment, the first material layer 1121 may have a single-layer structure including Al.

The second material layer 1131 may include a conductive material. In an embodiment, the second material layer 1131 may include at least one of Al, Pt, Pd, Ag, Mg, Au, Ni, Nd, Ir, Cr, Ca, Mo, Ti, W, and/or Cu, and may have a single-layer structure or a multilayered structure. In an embodiment, the second material layer 1131 may have a single-layer structure including Ti.

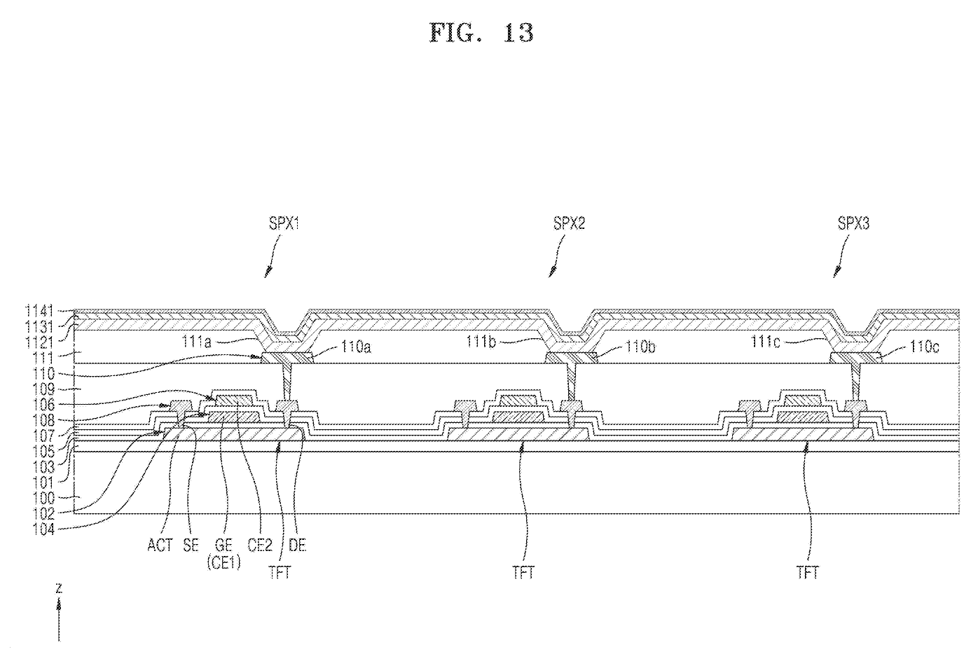

Referring to FIG. 13, a third material layer 1141 may be arranged on the second material layer 1131. The third material layer 1141 may entirely or substantially entirely cover the second material layer 1131.

The third material layer 1141 may include a conductive material. In an embodiment, the third material layer 1141 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the third material layer 1141 may include a reflective layer including Ag, Mg, Al, Pt, Pd, Au, Ni, Nd, Ir, Cr, or a suitable compound thereof.

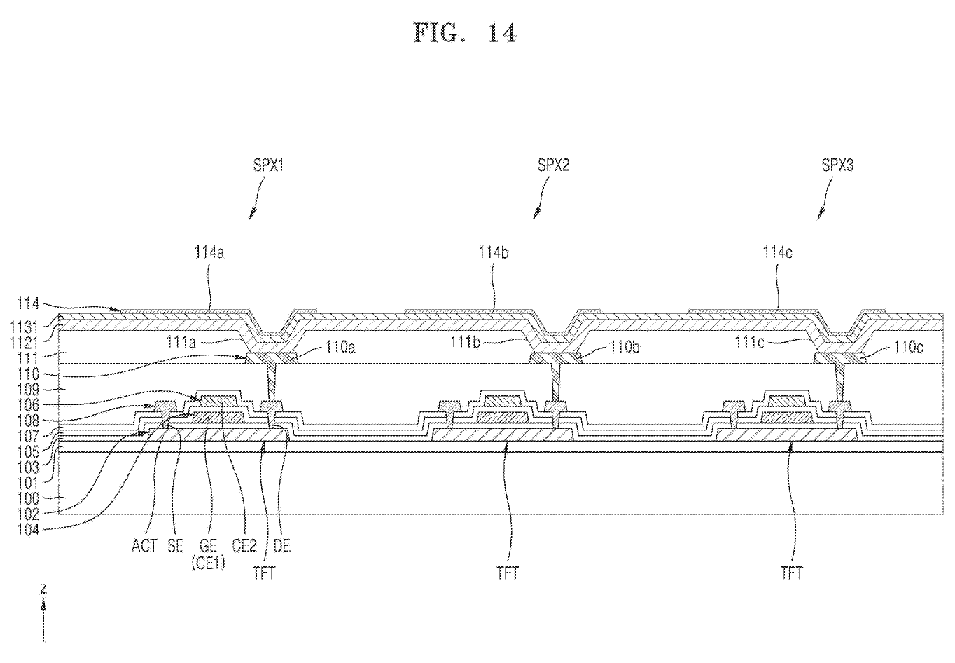

Referring to FIGS. 13 and 14, the seventh conductive layer 114 may be formed by etching the third material layer 1141. The seventh conductive layer 114 may include the first sub-pixel electrode 114a, the second sub-pixel electrode 114b, and the third sub-pixel electrode 114c. In other words, the first sub-pixel electrode 114a, the second sub-pixel electrode 114b, and the third sub-pixel electrode 114c may be patterned on the second material layer 1131. The seventh conductive layer 114, for example, the first sub-pixel electrode 114a to the third sub-pixel electrode 114c, may include the same material as that of the third material layer 1141.

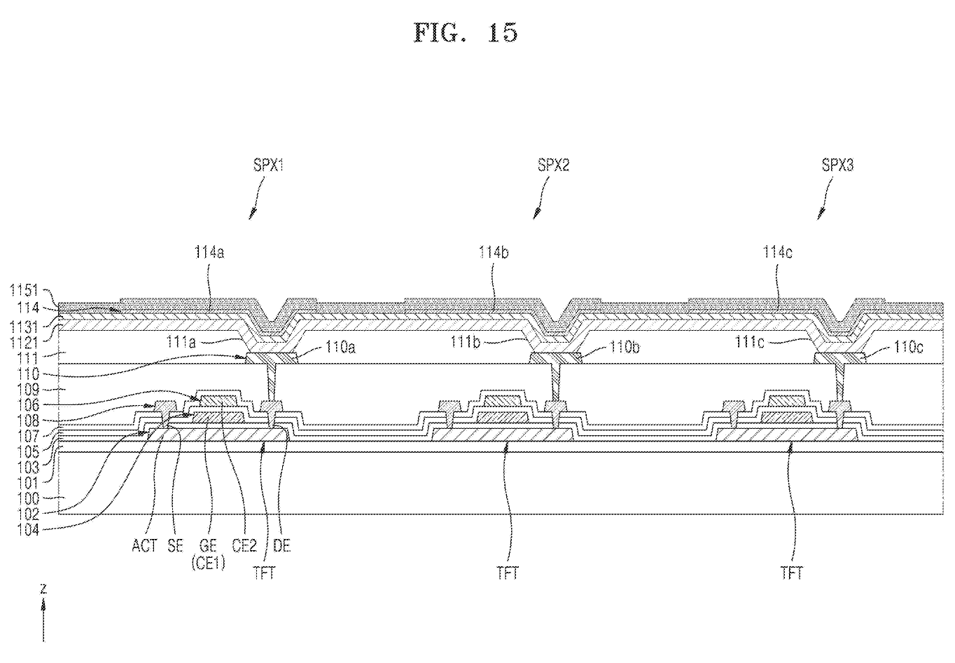

Referring to FIG. 15, a fourth material layer 1151 may be arranged on the seventh conductive layer 114. The fourth material layer 1151 may entirely or substantially entirely cover the seventh conductive layer 114. For example, the fourth material layer 1151 may entirely or substantially entirely cover the first sub-pixel electrode 114a to the third sub-pixel electrode 114c.

The fourth material layer 1151 may include an inorganic insulating material. In an embodiment, the fourth material layer 1151 may include at least one inorganic insulating material, such as SiO₂, SiNₓ, SiON, Al₂O₃, TiO₂, Ta₂O₅, HfO_{2,} or ZnO₂, and may have a single-layer structure or a multilayered structure. In an embodiment, the fourth material layer 1151 may have a single-layer structure including SiNₓ.

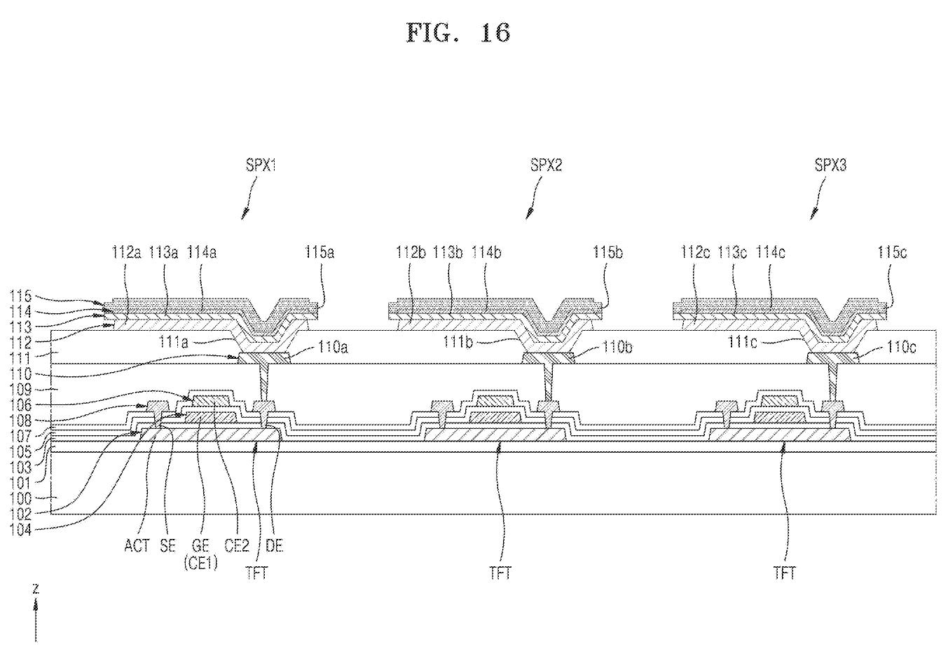

Referring to FIGS. 15 and 16, the fifth conductive layer 112, the sixth conductive layer 113, and the seventh conductive layer 115 may be formed by etching the first material layer 1121, the second material layer 1131, and the fourth material layer 1151, respectively.

The fifth conductive layer 112 may include the 1-1^{st} bank layer 112a, the 1-2^{nd} bank layer 112b, and the 1-3^{rd} bank layer 112c. In other words, the 1-1^{st} bank layer 112a, the 1-2^{nd} bank layer 112b, and the 1-3^{rd} bank layer 112c may be patterned on the sixth insulating layer 111. The fifth conductive layer 112, for example, the 1-1^{st} bank layer 112a, the 1-2^{nd} bank layer 112b, and the 1-3^{rd} bank layer 112c, may include the same material as that of the first material layer 1121.

The sixth conductive layer 113 may include the 2-1^{st} bank layer 113a, the 2-2^{nd} bank layer 113b, and the 2-3^{rd} bank layer 113c. In other words, the 2-1^{st} bank layer 113a, the 2-2^{nd} bank layer 113b, and the 2-3^{rd} bank layer 113c may be patterned on the sixth insulating layer 111. The sixth conductive layer 113, for example, the 2-1^{st} bank layer 113a, the 2-2^{nd} bank layer 113b, and the 2-3^{rd} bank layer 113c, may include the same material as that of the second material layer 1131.

Description of the detailed structures of the fifth conductive layer 112 and the sixth conductive layer 113 are the same as those described above with reference to FIG. 4. The fifth conductive layer 112 and the sixth conductive layer 113 may include materials with different selectivities from each other. In an embodiment, the fifth conductive layer 112 may include Al, and the sixth conductive layer 113 may include Ti. When an etching process is performed using an etchant (e.g., a specific or predetermined etchant), the fifth conductive layer 112 may be etched more than the sixth conductive layer 113. As a result, tip structures (or undercut structures) of the fifth conductive layer 112 and the sixth conductive layer 113 may be implemented.

The seventh insulating layer 115 may include the first protective layer 115a, the second protective layer 115b, and the third protective layer 115c. The seventh insulating layer 115, for example, the first protective layer 115a to the third protective layer 115c, may include the same material as that of the fourth material layer 1151.

In the current stage of the method of manufacturing the display panel 2, the first protective layer 115a may not include an open portion in the area where the first protective layer 115a overlaps with the central portion of the first sub-pixel electrode 114a. Similarly, the second protective layer 115b may not include an open portion in the area where the second protective layer 115b overlaps with the central portion of the second sub-pixel electrode 114b. Similarly, the third protective layer 115c may not include an open portion in the area where the third protective layer 115c overlaps with the central portion of the third sub-pixel electrode 114c. Therefore, in the current stage of the method of manufacturing the display panel 2, the seventh insulating layer 115 may entirely or substantially entirely cover the seventh conductive layer 114. For example, in the current stage of the method of manufacturing a display panel, the first protective layer 115a may entirely or substantially entirely cover the first sub-pixel electrode 114a, the second protective layer 115b may entirely or substantially entirely cover the second sub-pixel electrode 114b, and the third protective layer 115c may entirely or substantially entirely cover the third sub-pixel electrode 114c.

The processes of etching the first material layer 1121, the second material layer 1131, and/or the fourth material layer 1151 may be performed either concurrently (e.g., simultaneously or substantially simultaneously) with each other, or separately.

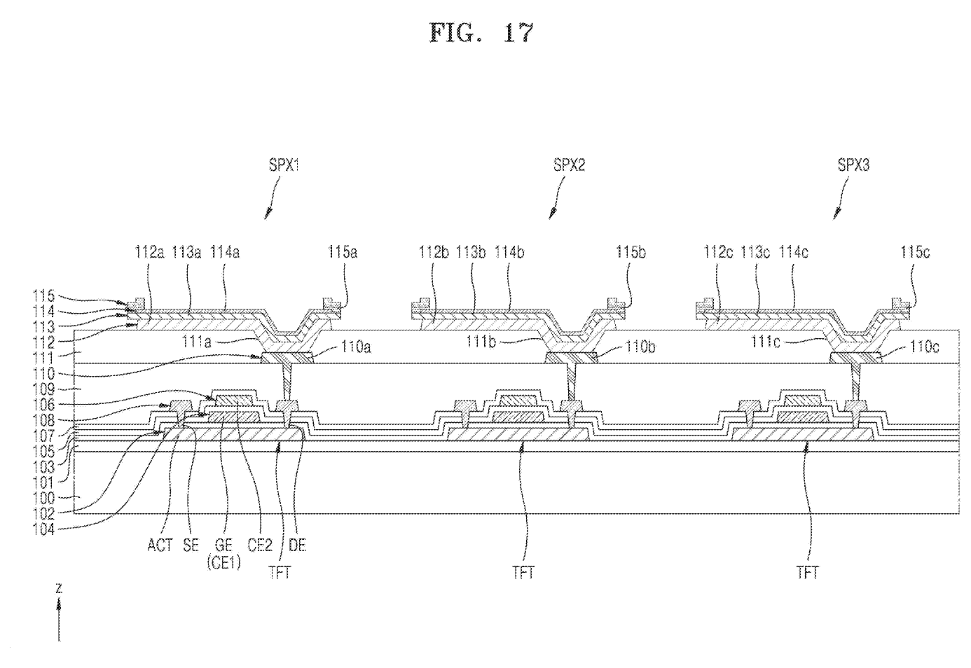

Referring to FIG. 17, the seventh insulating layer 115 may be additionally etched.

In an embodiment, an opening overlapping with the central portion of the first sub-pixel electrode 114a may be formed by etching the first protective layer 115a. In other words, the first protective layer 115a may include an open portion to expose the central portion of the first sub-pixel electrode 114a. In other words, the first protective layer 115a may be etched to cover (e.g., to cover only) the edge region (e.g., the edge) of the first sub-pixel electrode 114a.

In an embodiment, an opening overlapping with the central portion of the second sub-pixel electrode 114b may be formed by etching the second protective layer 115b. In other words, the second protective layer 115b may include an open portion to expose the central portion of the second sub-pixel electrode 114b. In other words, the second protective layer 115b may be etched to cover (e.g., to cover only) the edge region (e.g., the edge) of the second sub-pixel electrode 114b.

In an embodiment, an opening overlapping with the central portion of the third sub-pixel electrode 114c may be formed by etching the third protective layer 115c. In other words, the third protective layer 115c may include an open portion to expose the central portion of the third sub-pixel electrode 114c. In other words, the third protective layer 115c may be etched to cover (e.g., to cover only) the edge region (e.g., the edge) of the third sub-pixel electrode 114c.

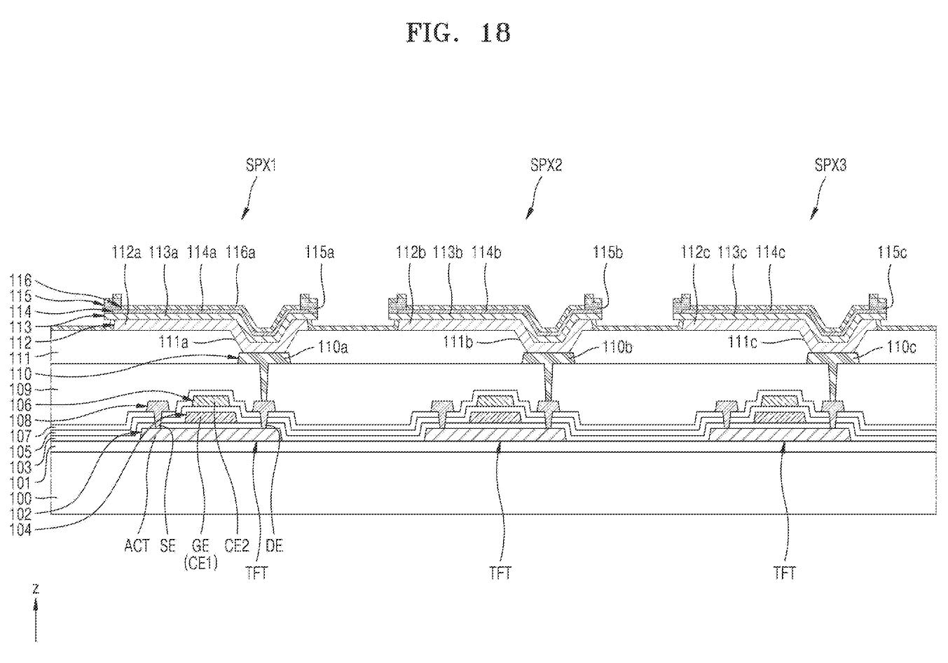

Referring to FIG. 18, the intermediate layer 116, for example, the first intermediate layer 116a, may be arranged on the sixth insulating layer 111, the fifth conductive layer 112, the sixth conductive layer 113, the seventh conductive layer 114, and the seventh insulating layer 115. The first intermediate layer 116a may entirely or substantially entirely cover the sixth insulating layer 111, the fifth conductive layer 112, the sixth conductive layer 113, the seventh conductive layer 114, and the seventh insulating layer 115.

The first intermediate layer 116a may be entirely arranged (e.g., coated) along the shapes of the sixth insulating layer 111, the fifth conductive layer 112, the sixth conductive layer 113, the seventh conductive layer 114, and the seventh insulating layer 115. Therefore, in the current stage of the method of manufacturing the display panel 2, the first intermediate layer 116a may entirely or substantially entirely cover the sixth insulating layer 111, the fifth conductive layer 112, the sixth conductive layer 113, the seventh conductive layer 114, and the seventh insulating layer 115.

A portion of the first intermediate layer 116a may be arranged on the upper surface of the sixth insulating layer 111 between the 1-1^{st} bank layer 112a and the 1-2^{nd} bank layer 112b, and between the 1-2^{nd} bank layer 112b and the 1-3^{rd} bank layer 112c, and may directly contact the sixth insulating layer 111. The portion of the first intermediate layer 116a may cover the side surfaces of the 1-1^{st} bank layer 112a, the 1-2^{nd} bank layer 112b, and the 1-3^{rd} bank layer 112c. In addition, the portion of the first intermediate layer 116a may directly contact a portion (e.g., a tip) of each of the 2-1^{st} bank layer 113a to the 2-3^{rd} bank layer 113c.

Another portion of the first intermediate layer 116a may be arranged on the first sub-pixel electrode 114a to the third sub-pixel electrode 114c. Other portions of the first intermediate layer 116a may be arranged on the first protective layer 115a to the third protective layer 115c.

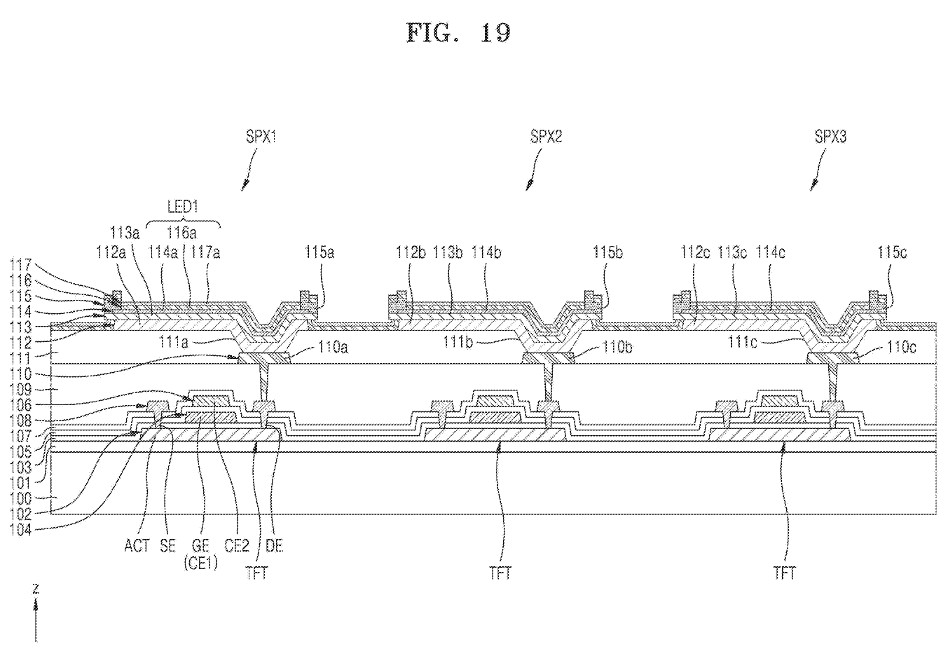

Referring to FIG. 19, the first opposite electrode 117a may be arranged on the first intermediate layer 116a. The first opposite electrode 117a may entirely or substantially entirely cover the first intermediate layer 116a.

Similar to the first intermediate layer 116a, the first opposite electrode 117a may be entirely arranged (e.g., coated) along the shapes of the sixth insulating layer 111, the fifth conductive layer 112, the sixth conductive layer 113, the seventh conductive layer 114, and the seventh insulating layer 115. Therefore, in the current stage of the method of manufacturing the display panel 2, the first opposite electrode 117a may entirely or substantially entirely cover the first intermediate layer 116a.

A portion of the first opposite electrode 117a may be arranged on the upper surface of the first intermediate layer 116a between the 1-1^{st} bank layer 112a and the 1-2^{nd} bank layer 112b, and between the 1-2^{nd} bank layer 112b and the 1-3^{rd} bank layer 112c. The portion of the first opposite electrode 117a may directly contact a portion (e.g., a tip) of each of the 2-1^{st} bank layer 113a to the 2-3^{rd} bank layer 113c.

Another portion of the first opposite electrode 117a may be arranged on the first sub-pixel electrode 114a to the third sub-pixel electrode 114c. Other portions of the first opposite electrode 117a may be arranged on the first protective layer 115a to the third protective layer 115c.

In an embodiment, in the current stage of the method of manufacturing the display panel 2, it may be understood that the first light-emitting diode LED1 is formed through a portion of the first intermediate layer 116a and a portion of the first opposite electrode 117a arranged on the first sub-pixel electrode 114a.

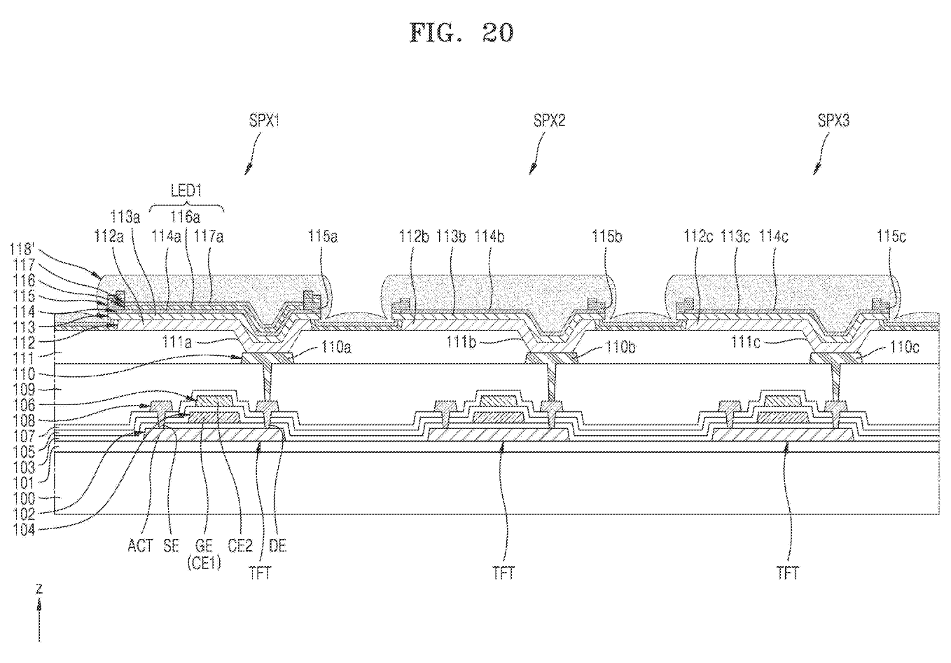

Referring to FIG. 20, a preliminary layer 118' may be arranged on the first opposite electrode 117a. The preliminary layer 118' may entirely or substantially entirely cover the first opposite electrode 117a and the first intermediate layer 116a.

The preliminary layer 118' may include an inorganic insulating material. In an embodiment, the preliminary layer 118' may include at least one inorganic insulating material, such as SiO₂, SiNₓ, SiON, Al₂O₃,TiO₂,Ta₂O₅, HfO₂, or ZnO₂.

In an embodiment, the preliminary layer 118' may be arranged through CVD. Accordingly, a portion of the preliminary layer 118' may be arranged along the shape of each of the space between the 1-1^{st} bank layer 112a and the 1-2^{nd} bank layer 112b, and the space between the 1-2^{nd} bank layer 112b and the 1-3^{rd} bank layer 112c.

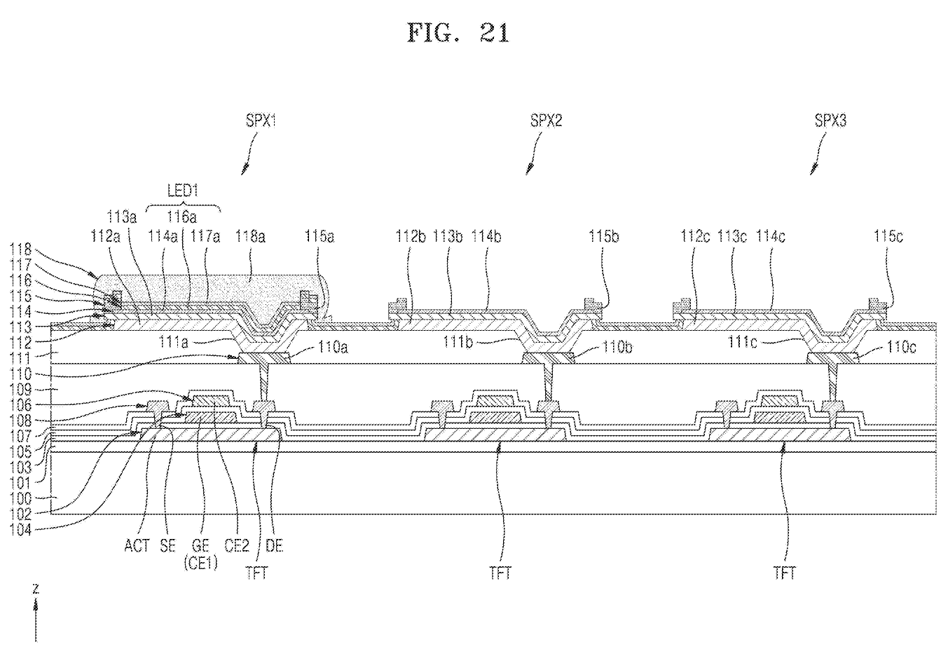

Referring to FIGS. 20 and 21, the 1-1^{st} encapsulation layer 118a may be formed by etching the preliminary layer 118'.

The remaining portions of the preliminary layer 118', except for a portion of the preliminary layer 118' corresponding to the first sub-pixel SPX1 or the first light-emitting diode LED1, may be removed. Accordingly, portions of the preliminary layer 118', which overlap with the 1-1^{st} bank layer 112a, the 2-1^{st} bank layer 113a, and the first sub-pixel electrode 114a, may only remain, and such portions may be understood as the 1-1^{st} encapsulation layer 118a. The 1-1^{st} encapsulation layer 118a may include the same material as that of the preliminary layer 118'.

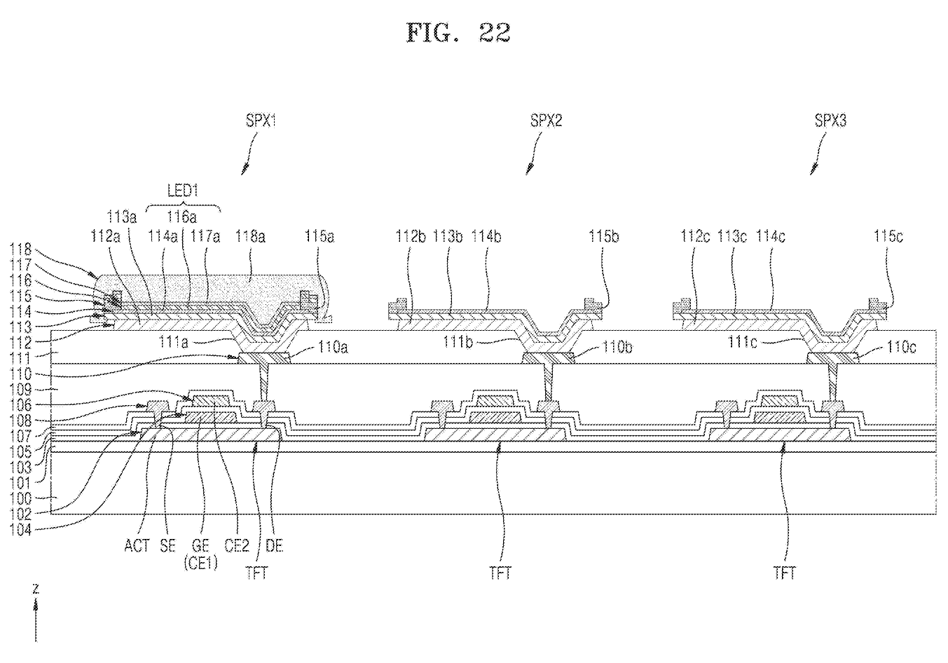

Referring to FIG. 22, the first intermediate layer 116a and the first opposite electrode 117a may be etched.

Except a portion of the first intermediate layer 116a corresponding to the first sub-pixel SPX1, the remaining portions of the first intermediate layer 116a may be removed. In other words, except a portion of the first intermediate layer 116a arranged on the first sub-pixel electrode 114a or the first protective layer 115a, the remaining portions of the first intermediate layer 116a may be removed. In other words, except a portion of the first intermediate layer 116a covered by the 1-1^{st} encapsulation layer 118a, the remaining portions of the first intermediate layer 116a may be removed. Accordingly, the first intermediate layer 116a may remain only on the first sub-pixel electrode 114a and the first protective layer 115a, and may be entirely or substantially entirely covered by the 1-1^{st} encapsulation layer 118a.

Similarly, the remaining portions of the first opposite electrode 117a may be removed, except a portion of the first opposite electrode 117a corresponding to the first sub-pixel SPX1. In other words, except a portion of the first opposite electrode 117aarranged on the first sub-pixel electrode 114a or the first protective layer 115a, the remaining portions of the first opposite electrode 117a may be removed. In other words, except a portion of the first opposite electrode 117a covered by the 1-1^{st} encapsulation layer 118a, the remaining portions of the first opposite electrode 117amay be removed. Accordingly, the first opposite electrode 117a may remain only on the first sub-pixel electrode 114a and the first protective layer 115a, and may be entirely or substantially entirely covered by the 1-1^{st} encapsulation layer 118a.

As a result, the first light-emitting diode LED1 and the 1-1^{st} encapsulation layer 118a, which correspond to the first sub-pixel SPX1, may be formed. The first light-emitting diode LED1 may be entirely or substantially entirely covered by the 1-1^{st} encapsulation layer 118a. For example, the first sub-pixel electrode 114a, the first intermediate layer 116a, and the first opposite electrode 117a may be entirely or substantially entirely covered by the 1-1^{st} encapsulation layer 118a.

As portions of the first intermediate layer 116a and the first opposite electrode 117a, which are arranged between the side surfaces of the 1-1^{st} encapsulation layer 118a and the 1-1^{st} bank layer 112a, are removed, a space may be formed between the 1-1^{st} encapsulation layer 118a and the 1-1^{st} bank layer 112a.

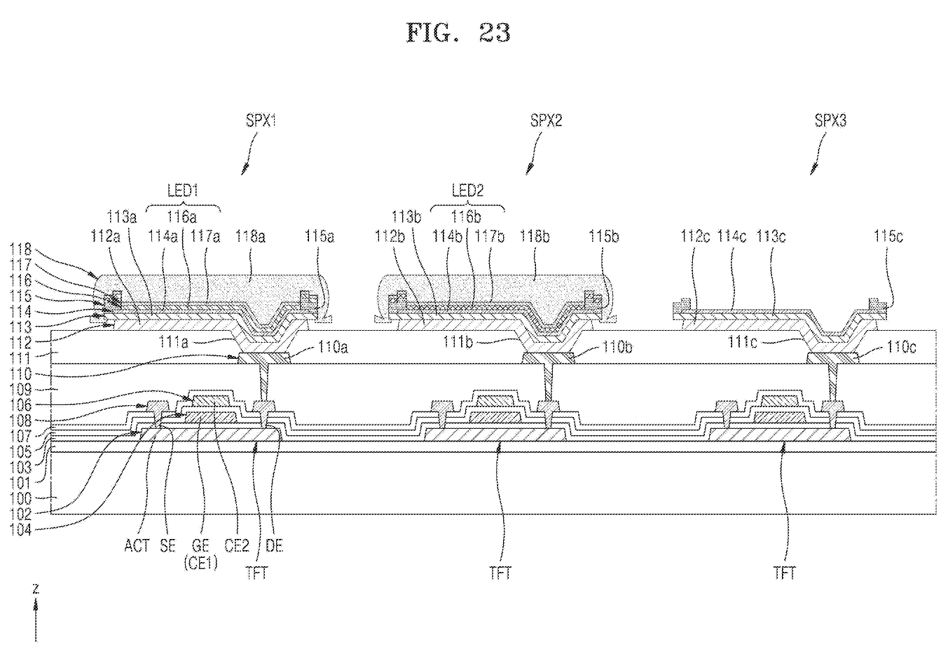

Referring to FIG. 23, the second light-emitting diode LED2 and the 1-2^{nd} encapsulation layer 118b, which correspond to the second sub-pixel SPX2, may be formed. The method of forming the second light-emitting diode LED2 and the 1-2^{nd} encapsulation layer 118b may be similar to (or the same or substantially the same as) the method of forming the first light-emitting diode LED1 and the 1-1^{st} encapsulation layer 118a described above with reference to FIGS. 18 to 22.

Similar to the first light-emitting diode LED1 and the 1-1^{st} encapsulation layer 118a, the second light-emitting diode LED2 may be entirely or substantially entirely covered by the 1-2^{nd} encapsulation layer 118b. For example, the second sub-pixel electrode 114b, the second intermediate layer 116b, and the second opposite electrode 117b may be entirely or substantially entirely covered by the 1-2^{nd} encapsulation layer 118b.

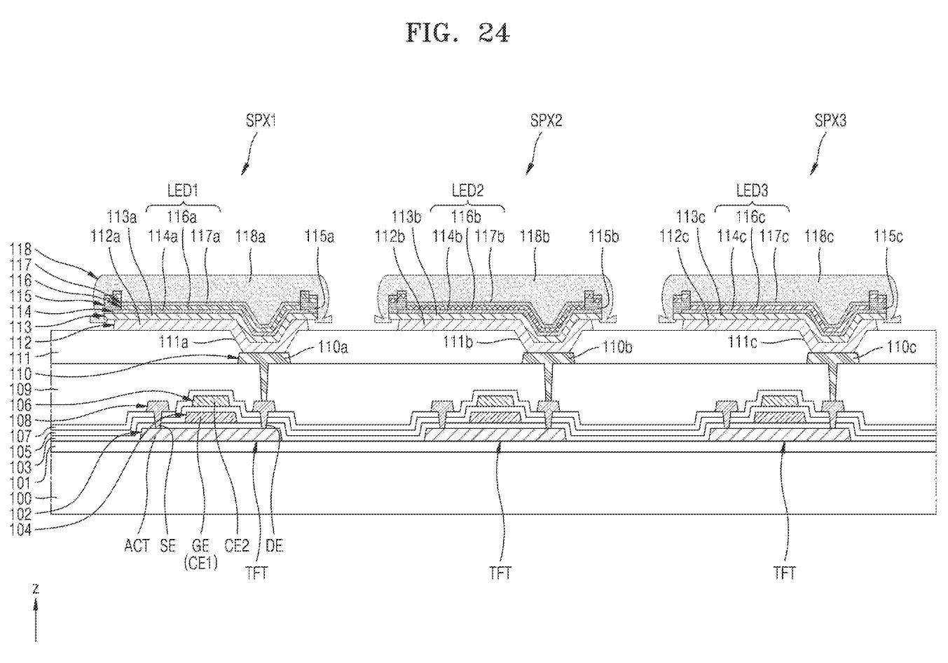

Referring to FIG. 24, the third light-emitting diode LED3 and the 1-3^{rd} encapsulation layer 118c, which correspond to the third sub-pixel SPX3, may be formed. The method of forming the third light-emitting diode LED3 and the 1-3^{rd} encapsulation layer 118c may be similar to (or the same or substantially the same as) the method of forming the first light-emitting diode LED1 and the 1-1^{st} encapsulation layer 118a described above with reference to FIGS. 18 to 22.

Similar to the first light-emitting diode LED1 and the 1-1^{st} encapsulation layer 118a, the third light-emitting diode LED3 may be entirely or substantially entirely covered by the 1-3^{rd} encapsulation layer 118c. For example, the third sub-pixel electrode 114c, the third intermediate layer 116c, and the third opposite electrode 117c may be entirely or substantially entirely covered by the 1-3^{rd} encapsulation layer 118c.

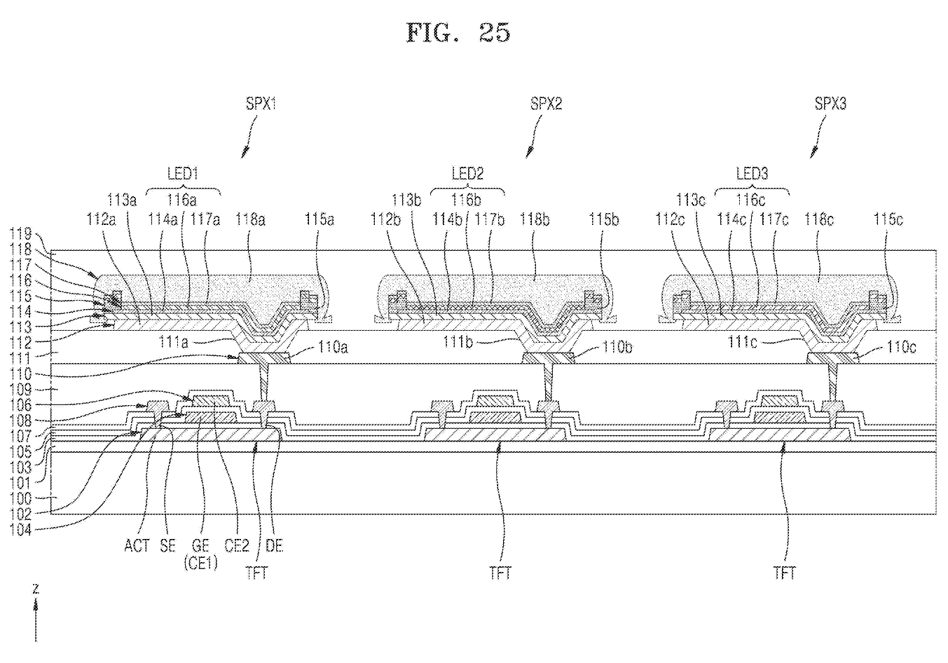

Referring to FIG. 25, the second encapsulation layer 119 may be arranged on the first encapsulation layer 118. The second encapsulation layer 119 may entirely or substantially entirely cover the first encapsulation layer 118, for example, the 1-1^{st} encapsulation layer 118a to the 1-3^{rd} encapsulation layer 118c. The second encapsulation layer 119 may directly contact the 1-1^{st} bank layer 112a and the 1-2^{nd} bank layer 112b, while filling the gap between the 1-1^{st} encapsulation layer 118a and the 1-2^{nd} encapsulation layer 118b. The second encapsulation layer 119 may directly contact the 1-2^{nd} bank layer 112b and the 1-3^{rd} bank layer 112c, while filling the gap between the 1-2^{nd} encapsulation layer 118b and the -3^{rd} encapsulation layer 118c. In addition, the second encapsulation layer 119 may directly contact the sixth insulating layer 111 in the gap between the 1-1^{st} encapsulation layer 118a and the 1-2^{nd} encapsulation layer 118b, and in the gap between the 1-2^{nd} encapsulation layer 118b and the 1-3^{rd} encapsulation layer 118c.

In an embodiment, the second encapsulation layer 119 may include an organic insulating material. For example, the second encapsulation layer 119 may include a polymer-based material. Examples of the polymer-based material may include a silicon-based resin, an acrylic resin, an epoxy-based resin, polyimide, polyethylene, and the like.

In an embodiment, as described above with reference to FIG. 5, the second encapsulation layer 119 may also include an inorganic insulating material. For example, the second encapsulation layer 119 may include at least one inorganic insulating material, such as SiO₂, SiNₓ, SiON, Al₂O₃,TiO₂,Ta₂O₅, HfO₂, or ZnO₂. In this case, the second encapsulation layer 119 may have the shape described above with reference to FIG. 5.

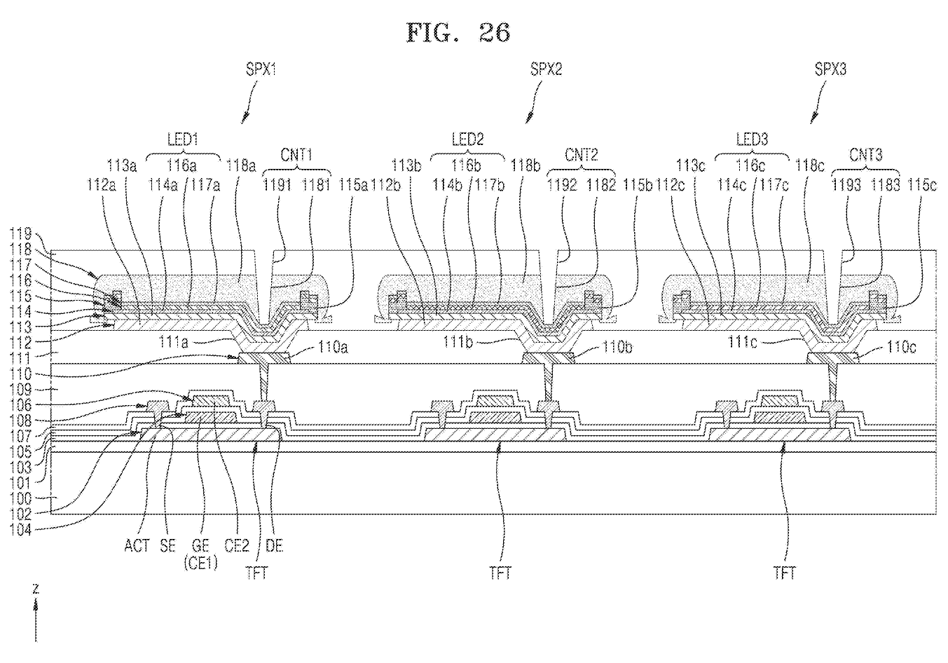

Referring to FIG. 26, the first connecting portion CNT1 to the third connecting portion CNT3 may be formed. The first connecting portion CNT1 may include the 1-1^{st}connecting opening 1181 and the 2-1^{st} connecting opening 1191. The second connecting portion CNT2 may include the 1-2^{nd} connecting opening 1182 and the 2-2^{nd} connecting opening 1192. The third connecting portion CNT3 may include the 1-3^{rd} connecting opening 1183 and the 2-3^{rd} connecting opening 1193.

The 1-1^{st} connecting opening 1181 and the 2-1^{st} connecting opening 1191 may be formed by etching the 1-1^{st} encapsulation layer 118a and the second encapsulation layer 119. A portion of the upper surface of the first opposite electrode 117a may be exposed through the 1-1^{st} connecting opening 1181 and the 2-1^{st} connecting opening 1191. The 1-2^{nd} connecting opening 1182 and the 2-2^{nd} connecting opening 1192 may be formed by etching the 1-2^{nd} encapsulation layer 118b and the second encapsulation layer 119. A portion of the upper surface of the second opposite electrode 117b may be exposed through the 1-2^{nd} connecting opening 1182 and the 2-2^{nd} connecting opening 1192. The 1-3^{rd} connecting opening 1183 and the 2-3^{rd} connecting opening 1193 may be formed by etching the 1-3^{rd}encapsulation layer 118c and the second encapsulation layer 119. A portion of the upper surface of the third opposite electrode 117c may be exposed through the 1-3^{rd} connecting opening 1183 and the 2-3^{rd} connecting opening 1193.

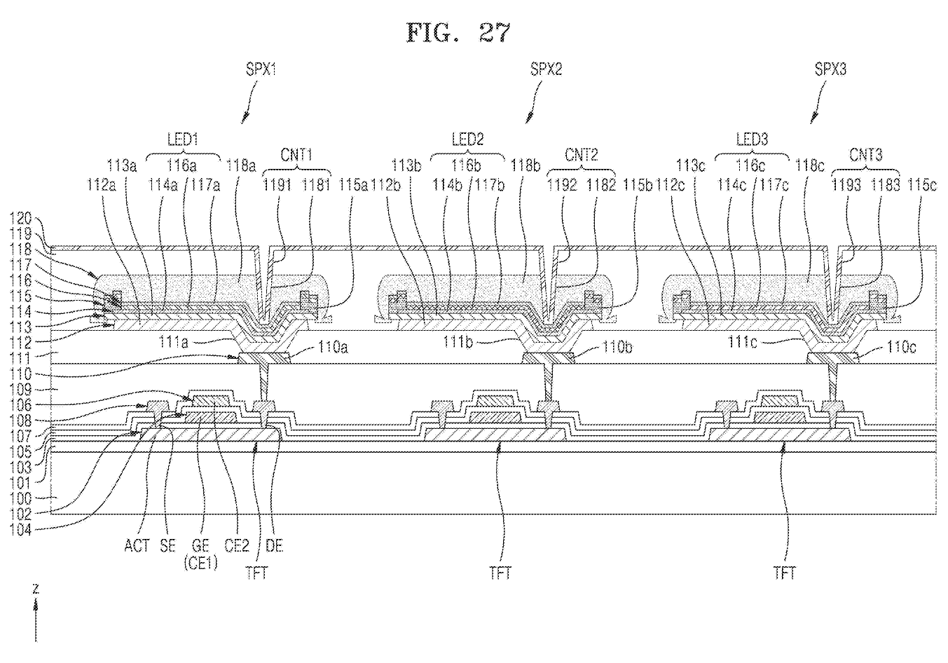

Referring to FIG. 27, the upper electrode 120 may be arranged on the second encapsulation layer 119. A portion of the upper electrode 120 may be arranged in the first connecting portion CNT1, and may be connected to the first opposite electrode 117a through a direct contact. A portion of the upper electrode 120 may be arranged in the second connecting portion CNT2, and may be connected to the second opposite electrode 117b through a direct contact. A portion of the upper electrode 120 may be arranged in the third connecting portion CNT3, and may be connected to the third opposite electrode 117c through a direct contact.

The shape in which the upper electrode 120 is arranged is the same as that described above with reference to FIGS. 8 to 10. In an embodiment, the upper electrode 120 may be arranged to entirely or substantially entirely cover the first light-emitting diode LED1 to the third light-emitting diode LED3. In an embodiment, the upper electrode 120 may be patterned to overlap with the first light-emitting diode LED1 to the third light-emitting diode LED3 in (e.g., only in) the first connecting portion CNT1 to the third connecting portion CNT3.

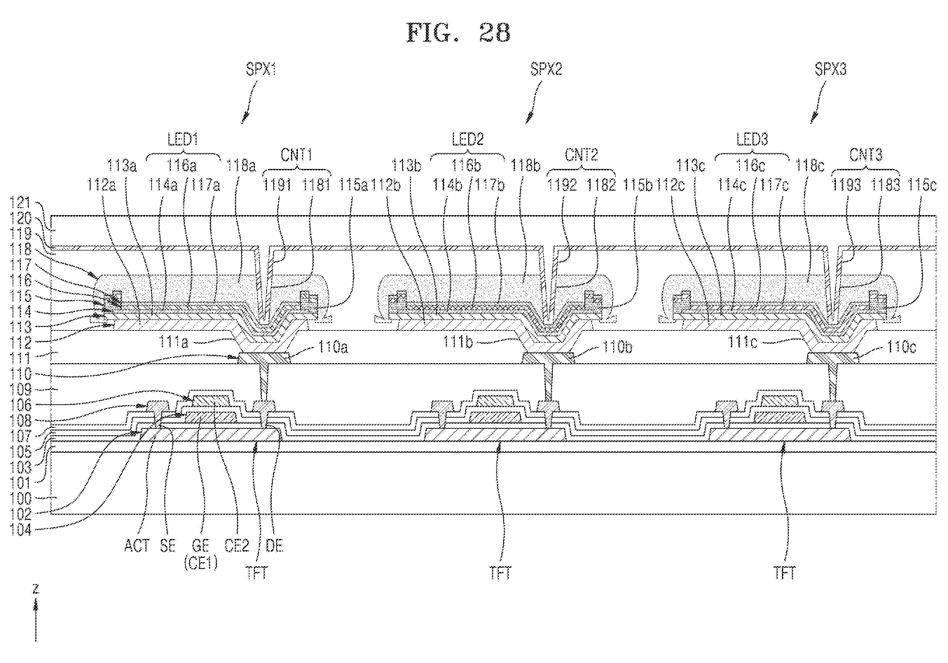

Referring to FIG. 28, the third encapsulation layer 121 may be arranged on the upper electrode 120. The third encapsulation layer 121 may entirely or substantially entirely cover the upper electrode 120. The structure of the third encapsulation layer 121 is the same as that described above.

According to the one or more embodiments, a sub-pixel electrode may receive a voltage by directly contacting a bank layer, and an opposite electrode may receive a voltage through an upper electrode that may be separately provided. Accordingly, in some embodiments, a voltage may be stably applied to both the sub-pixel electrode and the opposite electrode. As such, in some embodiments a failure in applying a voltage to an opposite electrode may be prevented or substantially prevented (or at least reduced).

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in (e.g., penetrating) the appended claims, and their equivalents.

What is claimed is:

1. A display panel comprising:
a substrate;
a bank layer on the substrate;
a light-emitting diode comprising a sub-pixel electrode, an intermediate layer, and an opposite electrode sequentially on the bank layer;
a first encapsulation layer on the opposite electrode, and having a first connecting opening overlapping with the opposite electrode; and
an upper electrode on the first encapsulation layer, and connected to the opposite electrode through the first connecting opening in the first encapsulation layer.

2. The display panel of claim 1, wherein the bank layer comprises a first bank layer, and a second bank layer on the first bank layer, the second bank layer comprising a tip extending beyond an edge of the first bank layer.

3. The display panel of claim 1, wherein the first encapsulation layer entirely covers the light-emitting diode, and partially covers the bank layer.

4. The display panel of claim 1, further comprising a thin-film transistor under the bank layer,
wherein the sub-pixel electrode is electrically connected to the thin-film transistor through the bank layer.

5. The display panel of claim 1, further comprising a second encapsulation layer between the first encapsulation layer and the upper electrode and having a second connecting opening overlapping with the first connecting opening in the first encapsulation layer,
wherein the upper electrode is connected to the opposite electrode through the first connecting opening in the first encapsulation layer and the second connecting opening in the second encapsulation layer.

6. The display panel of claim 1, further comprising a third encapsulation layer covering the upper electrode.

7. The display panel of claim 1, further comprising a protective layer on the bank layer, and covering an edge region of the sub-pixel electrode.

8. The display panel of claim 7, wherein a portion of the intermediate layer and a portion of the opposite electrode are on the protective layer.

9. The display panel of claim 1, wherein, in a plan view, the upper electrode surrounds around at least a portion of the light-emitting diode, and overlaps with the light-emitting diode in an area corresponding to the first connecting opening.

10. An electronic device comprising:
a display panel; and
a housing accommodating the display panel,
wherein the display panel comprises:
a substrate;
a bank layer on the substrate;
a light-emitting diode comprising a sub-pixel electrode, an intermediate layer, and an opposite electrode sequentially on the bank layer;
a first encapsulation layer on the opposite electrode, and having a first connecting opening overlapping with the opposite electrode; and
an upper electrode on the first encapsulation layer, and connected to the opposite electrode through the first connecting opening in the first encapsulation layer.

11. A method of manufacturing a display panel, the method comprising:
arranging a bank layer on a substrate;
arranging, on the bank layer, a light-emitting diode comprising a sub-pixel electrode, an intermediate layer, and an opposite electrode;
arranging a first encapsulation layer on the light-emitting diode;
forming a first connecting opening in the first encapsulation layer; and
arranging an upper electrode on the first encapsulation layer to be connected to the opposite electrode of the light-emitting diode through the first connecting opening.

12. The method of claim 11, wherein the arranging of the bank layer comprises:
sequentially arranging a first material layer and a second material layer on the substrate; and
forming a first bank layer and a second bank layer by etching each of the first material layer and the second material layer,
wherein the second bank layer comprises a tip extending beyond an edge of the first bank layer.

13. The method of claim 11, wherein the arranging of the first encapsulation layer comprises:
arranging a preliminary layer to entirely cover both the light-emitting diode and the bank layer; and
forming the first encapsulation layer by etching the preliminary layer,
wherein the first encapsulation layer entirely covers the light-emitting diode, and partially covers the bank layer.

14. The method of claim 11, further comprising:
arranging a second encapsulation layer between the upper electrode and the first encapsulation layer; and
forming a second connecting opening in the second encapsulation layer, the second connecting opening overlapping with the first connecting opening in the first encapsulation layer.

15. The method of claim 14, wherein the upper electrode is connected to the opposite electrode through the first connecting opening in the first encapsulation layer and the second connecting opening in the second encapsulation layer.

16. The method of claim 11, further comprising arranging a third encapsulation layer to cover the upper electrode.

17. The method of claim 11, further comprising arranging a protective layer on the bank layer to cover an edge region of the sub-pixel electrode.

18. The method of claim 17, wherein a portion of the intermediate layer and a portion of the opposite electrode are arranged on the protective layer.

19. The method of claim 11, wherein the light-emitting diode entirely overlaps with the upper electrode in a plan view in the arranging of the upper electrode.

20. The method of claim 19, wherein, in a plan view, the upper electrode is patterned to partially surround around the light-emitting diode, and overlaps with the light-emitting diode in an area corresponding to the first connecting opening.
